(19) United States
(12) Patent Application Publication
(10) Pub. No.: US 2016/0329340 A1
(43) Pub. Date: Nov. 10, 2016

(54) NONVOLATILE MEMORY DEVICE

(71) Applicants: CHUL-JIN HWANG, SEONGNAM-SI (KR); HYUN-DO KIM, SEOUL (KR); DONG-HA SHIN, SUWON-SI (KR)

(72) Inventors: CHUL-JIN HWANG, SEONGNAM-SI (KR); HYUN-DO KIM, SEOUL (KR); DONG-HA SHIN, SUWON-SI (KR)

(21) Appl. No.: 15/083,418

(22) Filed: Mar. 29, 2016

(30) Foreign Application Priority Data
May 7, 2015 (KR) 10-2015-0063882

(51) Int. Cl. H01L 27/115; H01L 21/306; H01L 29/423

(52) U.S. Cl. CPC H01L 27/11556; H01L 29/4238; H01L 21/30604

(57) ABSTRACT

A nonvolatile memory device may include a first well area formed on a substrate, a plurality of channel layers disposed on the first well area and extended in a first direction substantially perpendicular to a surface of the first well area on which the channel layers are disposed, and a plurality of gate conductive layers stacked on the first well area along side walls of the plurality of channel layers, the plurality of gate conductive layers having a first edge area and a second edge area, wherein a first part of the first edge area is disposed outside of the first well area.

### CROSS-REFERENCE TO RELATED APPLICATION

This U.S. non-provisional patent application claims priority under 35 U.S.C. §119 to Korean Patent Application No. 10-2015-0063882 filed on May 7, 2015, the disclosure of which is incorporated by reference herein in its entirety.

### TECHNICAL FIELD

Exemplary embodiments of the inventive concept relate to a nonvolatile memory device, and more particularly, to a nonvolatile memory device and methods of manufacturing the nonvolatile memory device.

### DISCUSSION OF RELATED ART

Due to the increasing number of functions performed by information and telecommunication devices, high capacity and high integration memory devices are required. However, as a cell size is decreased to achieve high density, operation circuits and/or a wiring system included in the memory device may physically and electrically interfere with one another.

### SUMMARY

According to an exemplary embodiment of the inventive concept, a nonvolatile memory device includes a first well area formed on a substrate, a plurality of channel layers disposed on the first well area and extended in a first direction substantially perpendicular to a surface of the first well area on which the channel layers are disposed, and a plurality of gate conductive layers stacked on the first well area along side walls of the plurality of channel layers, the plurality of gate conductive layers having a first edge and a second edge, wherein a first part of a first edge is disposed outside of the first well area.

The first edge area is adjacent to an edge of the nonvolatile memory device. The first edge area is in a floating state. The first edge area is separated from other portions of the plurality of gate conductive layers by a word line cut area. The word line cut area is disposed in the first well area, and adjacent to a boundary of the first well area. The plurality of gate conductive layers are stacked with a step shape, and at least one gate conductive layer among the plurality of gate conductive layers is disposed outside of the first well area, and at least one gate conductive layer of the plurality of gate conductive layers is disposed inside the first well area.

The nonvolatile memory device further includes a second well area formed adjacent to the first well area on the substrate, wherein the second edge area of the plurality of gate conductive layers faces the second well area, wherein the second edge area is disposed inside the first well area. The second edge area is electrically connected to a semiconductor element formed on the second well area. A row decoder circuit is formed on the second well area, the row decoder circuit is configured to provide a voltage to the plurality of gate conductive layers. The nonvolatile memory device further includes a semiconductor integrated circuit disposed in another substrate and overlapped with the first well area, wherein the semiconductor integrated circuit is electrically connected to a memory cell array, and the memory cell array is formed by the plurality of channel layers and the plurality of gate conductive layers.

According to an exemplary embodiment of the inventive concept, a nonvolatile memory device includes a memory cell array including a plurality of stacked memory cells, and a peripheral circuit configured to write and read a data from the memory cell array, the memory cell array further includes a plurality of channel layers extended in a vertical direction from a cell array area formed on a first substrate, and a plurality of gate conductive layers stacked on the cell array area alongside the plurality of channel layers, wherein at least one edge area among edge areas of the plurality of gate conductive layers is disposed outside of the cell array area.

The cell array area is a first well area. The cell array area includes a first conductive well area and a second conductive well area, the first conductive well area is formed on the first substrate, and the second conductive well area is formed on the first conductive well area. The first substrate is a conductive substrate. The at least one edge area is disposed in a direction intersecting with an edge area electrically connected to the peripheral circuit. The edge area electrically connected to the peripheral circuit is disposed inside the cell array area. The peripheral circuit is formed at same level with the cell array area on the first substrate.

The peripheral circuit comprises a first peripheral circuit formed alongside the cell array area on the first substrate, and a second peripheral circuit formed on a second substrate, the second peripheral circuit electrically connected to the memory cell array, and the second substrate is overlapped by the first substrate. The first peripheral circuit comprises a circuit, and the circuit is configured to process data received or transmitted to/from the memory cell array. The peripheral circuit is overlapped by the memory cell array.

According to an exemplary embodiment of the inventive concept, a method of manufacturing a nonvolatile memory device includes forming a first well area on a first substrate, stacking a plurality of conductive layers on the first well area, wherein the plurality of conductive layers are stacked in a vertical direction, forming a plurality of channel layers extended in the vertical direction from the first well area, wherein the plurality of channel layers are formed by penetrating the plurality of conductive layers, and patterning the plurality of conductive layers to have steps, wherein a horizontal length of the first substrate is longer than a horizontal length of the first well area.

The step of patterning the plurality of conductive layers comprises etching the plurality of conductive layers to form a first edge area of the plurality of conductive layers outside of the first well area. The method further includes forming a peripheral circuit on a second substrate that is overlapped by the first substrate. The peripheral circuit is overlapped with the first well area in the vertical direction. The method further includes forming a second well area; and forming a peripheral circuit on the second well area, wherein the peripheral circuit controls a memory element formed on the first well area, the step of patterning comprises patterning a second edge area of the plurality of conductive layers to be disposed outside of the first well area, and the second edge area is not adjacent to the second well area.

According to an exemplary embodiment of the inventive concept, a nonvolatile memory device comprises: a substrate including a well area and a non-well area; and a plurality of memory cells stacked on the substrate in a first direction substantially perpendicular to a surface of the substrate on which the memory cells are stacked, wherein the memory cells include a plurality of gate conductive layers stacked in the first direction, and wherein a first portion of the gate conductive layers are disposed in the well area and a second portion of the gate conductive layers are disposed in the non-well area.

The gate conductive layers form word lines.

The word lines disposed in the non-well area are in a floated state.

The nonvolatile memory device has a cell over peripheral structure.

### BRIEF DESCRIPTION OF THE DRAWINGS

The above and other features of the inventive concept will become more apparent by describing in detail exemplary embodiments of the inventive concept with reference to the attached drawings.

FIG. 1a is a layout diagram illustrating a memory device according to an exemplary embodiment of inventive concept.

FIG. 1b is a cross-sectional diagram according to an exemplary embodiment of inventive concept.

FIG. 1c is a cross-sectional diagram according to an exemplary embodiment of the inventive concept.

FIG. 2 is a diagram illustrating a memory cell array according to an exemplary embodiment of the inventive concept.

FIG. 3 is a partial circuit diagram further illustrating a memory block of FIG. 2 according to an exemplary embodiment of the inventive concept.

FIG. 4 is a cross sectional diagram illustrating a memory device according to an exemplary embodiment of the inventive concept.

FIG. 5 is a cross sectional diagram illustrating a memory device according to an exemplary embodiment of the inventive concept.

FIG. 6a, 6b, 6c, 6d, 6e, 6f, and FIG. 6g are diagrams illustrating a method of manufacturing according to an exemplary embodiment of the inventive concept.

FIG. 7a, 7b, and FIG. 7c are diagrams illustrating a method of manufacturing according to an exemplary embodiment of the inventive concept.

FIG. 8a is a layout diagram illustrating a memory device according to an exemplary embodiment of the inventive concept.

FIG. 8b is a cross sectional diagram illustrating a memory device according to an exemplary embodiment of the inventive concept.

FIG. 9a is a layout diagram illustrating a memory device according to an exemplary embodiment of the inventive concept.

FIG. 9b is a cross sectional diagram illustrating a memory device of FIG. 9a according to an exemplary embodiment of the inventive concept.

FIG. 10, 11, 12, and FIG. 13 are a layout diagram illustrating a memory device according to exemplary embodiments of the inventive concepts.

FIG. 14 is a block diagram illustrating a nonvolatile memory device according to an exemplary embodiment of the inventive concept.

FIG. 15 is a block diagram illustrating a memory system according to an exemplary embodiment of the inventive concept.

FIG. 16 is a block diagram illustrating a memory card system according to an exemplary embodiment of the inventive concept.

FIG. 17 is a block diagram illustrating a computer system according to an exemplary embodiment of the inventive concept.

FIG. 18 is a block diagram illustrating a solid state drive (SSD) system according to an exemplary embodiment of the inventive concept.

### DETAILED DESCRIPTION OF THE EMBODIMENTS

Exemplary embodiments of the inventive concept will now be described more fully with reference to the accompanying drawings. The inventive concept may, however, be embodied in many alternate forms and should not be construed as limited to only the embodiments set forth herein.

It will be understood that when an element is referred to as being “connected” or “coupled” to another element, it may be directly connected or coupled to the other element or intervening elements may be present.

As used herein, the singular forms “a”, “an” and “the” are intended to include the plural forms as well, unless the context clearly indicates otherwise.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Exemplary embodiments of the inventive concept are described herein with reference to schematic illustrations of idealized embodiments (and intermediate structures) of the inventive concept. As such, variations from the shapes of the illustrations as a result, for example, of manufacturing techniques and/or tolerances, are to be expected. Thus, exemplary embodiments of the inventive concept should not be construed as limited to the particular shapes of regions illustrated herein but are to include deviations in shapes that result, for example, from manufacturing.

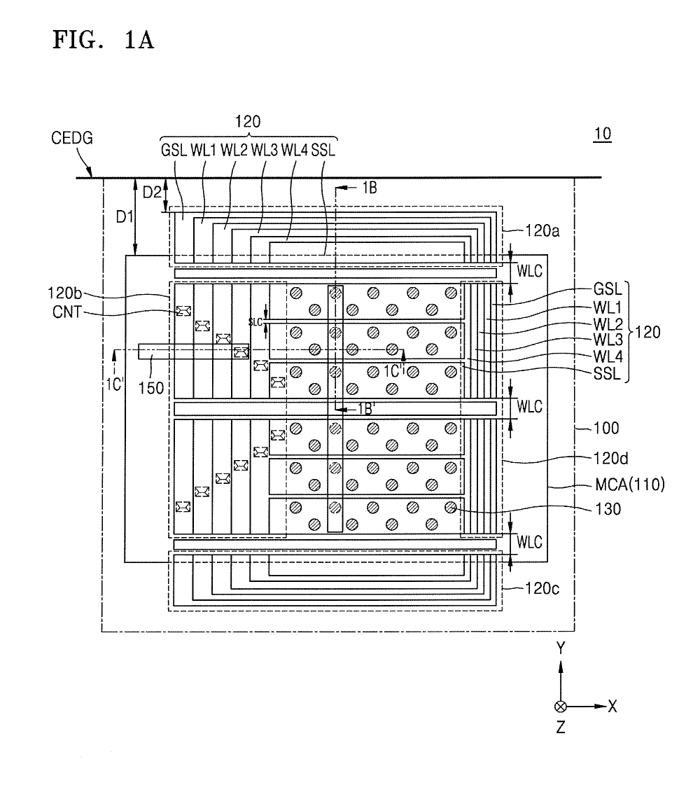

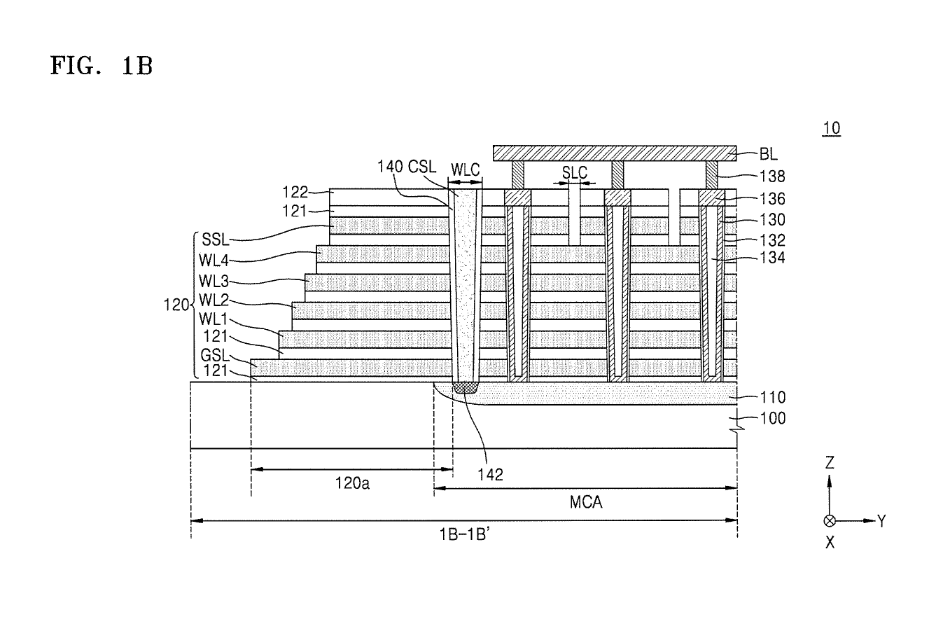

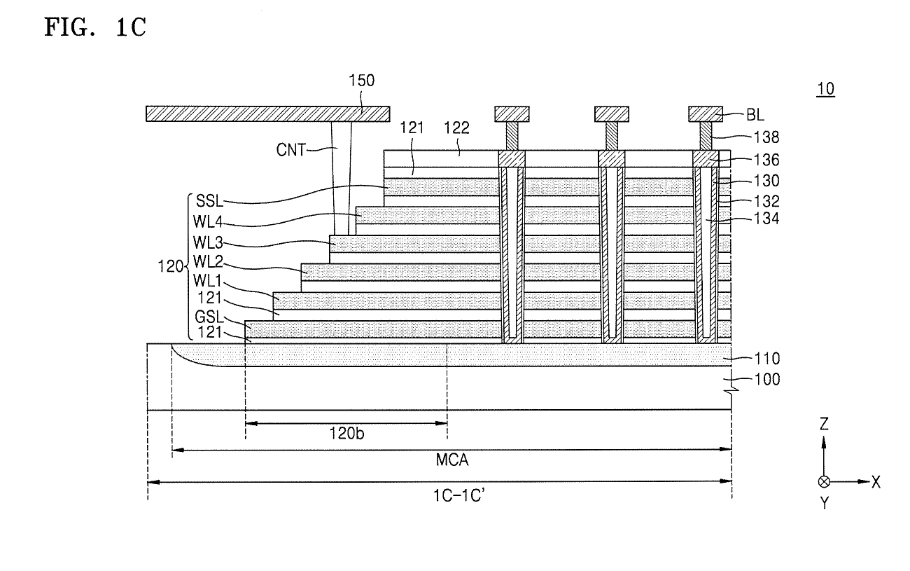

FIG. 1a is a layout diagram illustrating a memory device according to an exemplary embodiment of the inventive concept, and FIG. 1b and FIG. 1c are cross sectional diagrams of the memory device of FIG. 1a. FIG. 1b is a cross sectional view of line 1B-1B′ in FIG. 1a. FIG. 1c is a cross sectional view of line 1C-1C′ in FIG. 1a.

Referring to FIG. 1a through FIG. 1c, a substrate 100 of a memory device 10 may be included in a memory cell array area MCA. A peripheral circuit may be disposed at a periphery of the memory cell array area MCA. The peripheral circuit may be disposed under the memory cell array area MCA. The peripheral circuit may control data input or data output to/from the memory cell array area MCA.

The substrate 100 may include a main surface extended in a first direction (e.g., x-direction). For example, the substrate 100 may include Si, Ge and/or SiGe. The substrate 100 may include a poly silicon substrate, a silicon-on-insulator (SOI), and/or a germanium-on-insulator (GeOI).

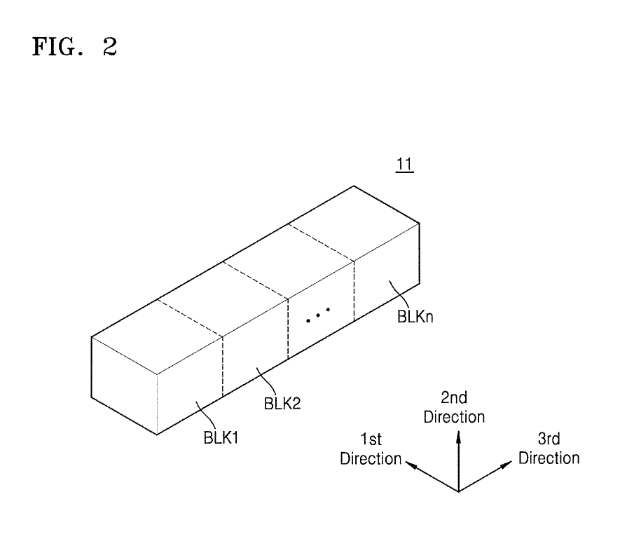

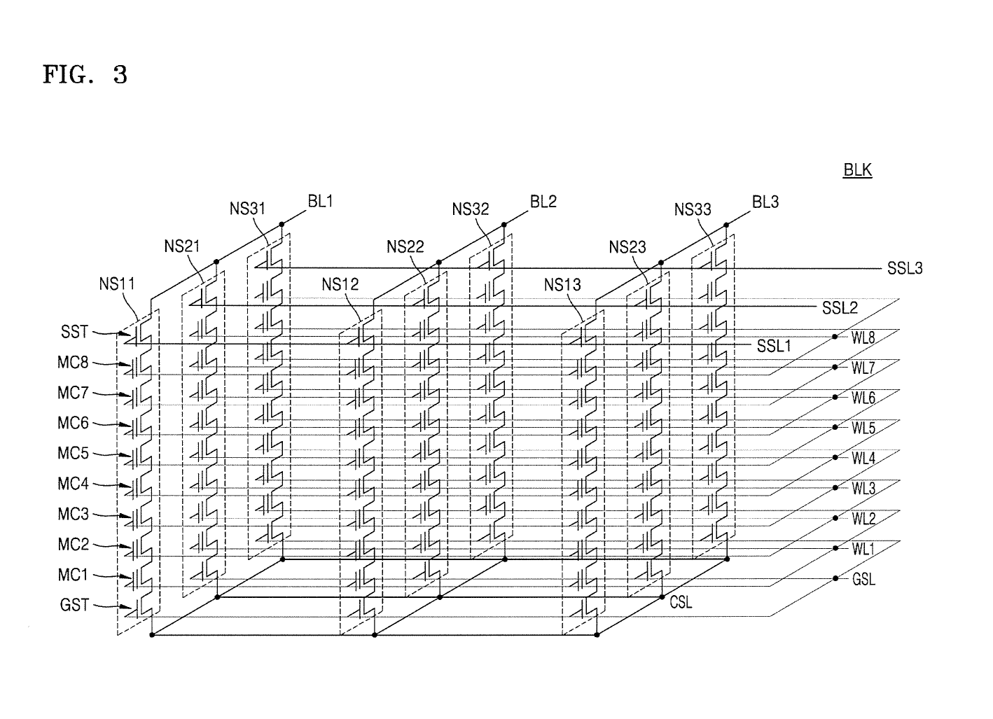

The memory cell array area MCA may be an area in which vertically stacked memory cells are disposed. For example, the memory cell array area MCA may be a well area 110 formed on the substrate 100. A memory cell array may be formed such that a plurality of channels and gate conductive layers are formed on the well area 110. The memory cell array may be formed in the memory cell array area MCA. The memory cell array may include a circuit configuration of FIG. 2 and/or FIG. 3.

The well area 110 may be a p-type well doped with a p-type impurity in the substrate 100. However, the inventive concept may be not limited to the p-type well. The well area 110 may be a n-type well. In addition, the well area 110 may be formed with an overlapped p-type well and n-type well.

Gate conductive layers 120 may be stacked on the well area 110. The gate conductive layers 120 may include a ground selection line GSL, word lines WL1˜WL4, and a string selection line SSL. The ground selection line GSL, the word lines WL1˜WL4 and the string selection line SSL may be formed sequentially on the well area 110. An insulating layer 121 may be disposed under each of the gate conductive layers 120. The insulating layer 121 may be disposed on each of the gate conductive layers 120. An area of gate conductive layer 120 may be reduced the farther it gets from the well area 110. Referring to FIG. 1b and FIG. 1c, the gate conductive layers 120 may be formed in a step structure.

In FIG. 1a through FIG. 1c, a structure including 4 word lines is described. However, the inventive concept is not limited thereto. For example, 8, 16, 32 or 64 word lines may stacked in a vertical direction between the ground selection line GSL and string selection line SSL. Each insulating layer 121 may be formed between adjacent word lines. In addition, a number of the ground selection lines and the string selection lines is not limited to 1. For example, 2 or more ground selection lines GSL may be stacked in the vertical direction. In addition, 2 or more string selection lines SSL may be stacked in the vertical direction.

The gate conductive layers 120 may include a plurality of edge areas 120a, 120b, 120c, 120d. Referring to FIG. 1b and FIG. 1c, a cross section of the plurality of edge areas 120a, 120b, 120c, 120d may be formed in a step pad structure. The step pad structure may be referred to as a “word line pad”. A contact CNT may be formed in an edge area among the plurality of edge areas 120a, 120b, 120c, 120d, for example, the second edge area 120b. The edge area 120b may be connected to an interconnection line 150 via the contact CNT. The edge area 120b may receive electrical signals from a peripheral circuit formed in another well area next to the well area 110 via the interconnection line 150. As illustrated in FIG. 1c, the second edge area 120b may be formed in the well area 110.

The gate conductive layers 120 may be separated by a word line cut area WLC. In addition, the string selection line SSL among the gate conductive layers 120 may be separated by a selection line cut SLC.

Referring to FIG. 1b, a common source line CSL may be formed in the word line cut area WLC. The common source line CSL may be extended in the first direction. A common source line spacer 140 may be formed at side walls of the common source line CSL. The common source line spacer 140 may include an insulating material. The common source line spacer 140 may prevent the common source line CSL and the gate conductive layers 120 from being electrically connected to each other. A common source area 142 may be formed in the well area 110. The common source area 142 may be extended in an extending direction of the word line cut area WLC (e.g., the x direction). The common source area 142 may be an impurity area highly doped with n-type impurities. The well area 110 and common source area 142 may form a p-n junction diode. The common source area 142 may function as a source area which provides a current to the vertical memory cells.

A channel layer 130 may penetrate the gate conductive layers 120 and insulating layers 121, and be extended in a third direction (e.g., z direction) which is perpendicular to an upper surface of the well area 110. A floor surface of the channel layer 130 may be connected to the upper surface of the well area 110. The channel layer 130 may be arranged with a predetermined distance according to the first direction and the second direction.

For example, the channel layer 130 may include a poly-silicon doped with impurities. The channel layer 130 may include a poly-silicon which is not doped with impurities. The channel layer 130 may be formed as a cup-shape (or clogged cylinder-shape) which extends in the vertical direction. A buried insulating film 134 may be filled in the inner wall of the channel layer 130. The upper surface of buried insulating film 134 may be disposed at the same level as the upper surface of channel layer 130. In addition, the channel layer 130 may be formed as a pillar-shape, and in this case, the buried insulating film 134 may not be formed.

A gate insulating layer 132 may be interposed between the channel layer 130 and the gate conductive layer 120. Selectively, a barrier metal layer may be further formed between the gate insulating layer 132 and the gate conductive layer 120.

A ground selection transistor GST of FIG. 3 may be formed by the gate insulating film 132, the ground selection line GSL, and a part of channel layer 130 adjacent to the ground selection line GSL. In addition, memory cell transistors MC1˜MC8 of FIG. 3 may be formed by the gate insulating film 132, the word lines WL1˜WL4, and a part of channel layer 130 adjacent to the word lines WL1˜WL4. A string selection transistor SST of FIG. 3 may be formed by the gate insulating film 132, the string selection line SSL, and a part of channel layer 130 adjacent to the string selection lines SSL.

A drain area 136 may be formed on the channel layer 130 and the gate insulating film 132. For example, the drain area 136 may include an impurity doped poly-silicon.

An etch stop layer 122 may be formed on a sidewall of the drain area 136. A surface of the etch stop layer 122 may be formed at the same level as the surface of drain area 136. The etch stop layer 122 may include an insulating material such as a silicon nitride, or silicon oxide. An interlayer insulating film may be formed on the etch stop layer 122. The etch stop layer 122 may cover a sidewall of the exposed gate conductive layer 120.

A bit line contact 138 may be formed on the drain area 136. A bit line BL may be formed on the bit line contact 138. The bit line BL may be extended in the second direction (e.g., the y direction). The plurality of channel layers 130 arranged in the second direction may be connected to the bit line BL.

Some or all of an edge area among the plurality of edge areas 120a, 120b, 120c, 120d may be disposed outside of the well area 110. In other words, as illustrated in FIG. 1b, some or all of at least one edge area may be not overlapped with the well area 110 in the vertical direction.

The edge area which is disposed outside of the well area 110 may not receive an electrical signal from a peripheral circuit. The edge area which is disposed outside of the well area 110 may be separated physically from other edge areas. For example, the edge area of the gate conductive layers 120 which is adjacent to an edge of semiconductor chip CEDG may be disposed outside of the well area 110. For example, the edge area disposed outside of the well area 110 may be disposed in a direction intersecting with an edge area among the plurality of edge areas 120a, 120b, 120c, 120d which does not receive an electrical signal from the interconnection line 150. However, the inventive concept may not be limited thereto, and the at least one edge area that is disposed outside of the well area 110 may be one of the other edge areas 120a, 120c, and 120d except for the second edge area 120b that receives an electrical signal from an external device.

Referring to FIG. 1a, an edge area disposed outside of the well area 110 may be the first edge area 120a and/or the third edge area 120c. The electrical signal may not be applied to the first edge area 120a and/or the third edge area 120c. The first edge area 120a and the third edge area 120c may be separated from the other edge areas, for example, the second edge area and the fourth edge area 120b and 120d, by the word line cut area WLC. The first edge area 120a and the third edge area 120c may be in a floating state. Since the first edge area 120a and the third edge area 120c are in contact with the substrate 100, a coupling phenomenon may occur. However, the coupling phenomenon may be prevented by floating the first edge area 120a and the third edge area 120c.

As described above, the step pad structure of the plurality of edge areas 120a, 120b, 120c, 120d may be referred to as a “word line pad”. According to an exemplary embodiment of the inventive concept, the second edge area 120b, may be disposed inside of the well area 110. Thus, electrical stability may be guaranteed. Some or all of the word line pads that are not used, for example, the first edge area 120a, the second edge area 120b, and the fourth edge area 120d may be disposed outside of the well area 110. Thus, the size of the semiconductor chip may be reduced.

If the word line pads that are not used are disposed inside of the well area 110 a size of the well area 110 may be increased. Thus, according to an exemplary embodiment of the inventive concept, the size of the memory cell array area MCA may be reduced by disposing unused word line pads outside of the well area 110, in other words, outside of memory cell array area MCA.

For ensuring the electrical stability of the memory cell array, the well area 110 may be spaced apart a predetermined distance D1 from the semiconductor chip edge CEDG or another well area. However, a distance that the unused word line pad is spaced apart from the semiconductor chip edge or the another well area, for example D2, may be shorter than the predetermined distance D1 of well area 110. Thus, the size of the semiconductor chip may be reduced by disposing the unused word line pad to the outside of well area 110, in other word, the outside of memory cell array MCA.

FIG. 2 is a block diagram illustrating the memory cell array 11 according to an exemplary embodiment of the inventive concept. Referring to FIG. 2, the memory cell array 11 may include a plurality of memory blocks BLK1˜BLKn. Each memory block may be a three dimensional structure (or vertical structure). Each memory block may include a structure extended in three dimensional directions (e.g., the x, y, z directions). For example, each memory block may include a plurality of NAND cell strings extended in the z direction (e.g., the third direction).

Each NAND string may be connected to a bit line BL, a string selection line SSL, a ground selection line GSL, word lines WL, and a common source line CSL. For example, each memory block may be connected to a plurality of bit lines BL, a plurality of string selection lines SSL, a plurality of ground selection lines GSL, a plurality of word lines WL, and the common source line CSL. The memory blocks BLK1˜BLKn will be described with reference to FIG. 3.

FIG. 3 is a circuit diagram illustrating a memory block of FIG. 2 according to an exemplary embodiment of the inventive concept.

Referring to FIG. 3, the memory block BLK may be a vertical structure NAND flash memory. Each of memory blocks BLK1˜BLKn of FIG. 2 may be implemented as the memory block of FIG. 3. The memory block BLK may include a plurality of NAND strings NS11˜NS33, a plurality of word lines WL1˜WL8, a plurality of bit lines BL1˜BL3, a ground selection line GSL, a plurality of string selection line SSL1˜SSL3, and common source line CSL. Herein, a number of NAND strings, a number of word lines, a number of bit lines, a number of ground selection lines, and/or a number of string selection lines may be changed variously.

The NAND string NS (for example, NS11) may be connected to the bit line BL and the common source line CSL. The NAND string NS may be disposed between the bit line BL and common source line CSL. Each NAND string (for example, NS11) may include a string selection transistor SST, a plurality of memory cells MC1˜MC8, and a ground selection transistor GST, connected in series.

NAND strings NS11, NS21, NS31 are disposed between the first bit line BL1 and the common source line CSL. NAND strings NS12, NS22, NS32 are disposed between the second bit line BL2 and the common source line CSL. NAND strings NS13, NS23, NS33 are disposed between the third bit line BL3 and the common source line CSL. In the following, the NAND string may be referred to as “string”.

Strings connected to a single bit line in common may constitute a single column. For example, strings NS11, NS21, NS31 connected in common to the first bit line BL1 may correspond to a first column. Strings NS12, NS22, NS32 connected in common to the second bit line BL2 may correspond to a second column. Strings NS13, NS23, NS33 connected in common to the third bit line BL3 may correspond to a third column.

Strings connected to a single string selection line may constitute a single row. For example, strings NS11, NS12, NS13 connected in common to a first string selection line SSL1 may correspond to a first row. Strings NS21, NS22, NS23 connected in common to a second string selection line SSL2 may correspond to a second row. Strings NS31, NS32, NS33 connected in common to a third string selection line SSL3 may correspond to a third row.

The string selection transistor SST may be connected to the string selection line (SSL1 to SSL3). The plurality of memory cells MC1 to MC8 may each be connected to a corresponding word line (WL1 to WL8). The ground selection transistor GST may be connected to the ground selection line GSL. The string selection transistor SST may be connected to corresponding bit line BL. The ground selection transistor GST may be connected to the common source line CSL.

Word lines at the same height (for example, WL1) may be connected in common. The string selection lines (for example, SSL1 to SSL3) may be separated from each other. In the case of programming memory cells connected to the first word line WL1 and included in the NAND strings (NS11, NS12, NS13), the first word line WL1 and the first string selection line SSL may be selected.

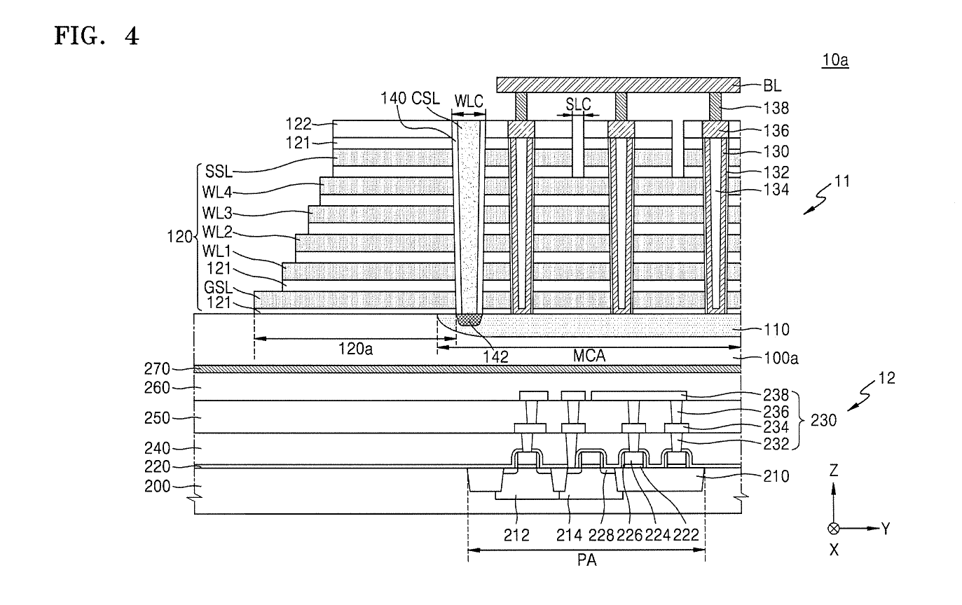

FIG. 4 is a cross sectional diagram illustrating a memory device according to an exemplary embodiment of the inventive concept. FIG. 4 is a cross sectional view of line 1B-1B′ of FIG. 1a. A layout of the memory device 10a is almost identical to that of FIG. 1a. Thus, the subject matter described with reference to FIG. 1a may be applied to the embodiment of FIG. 4.

In the memory device 10a, memory cell array 11 may be formed on peripheral circuit 12. This circuit structure of the memory device 10a may be referred to as a cell over peripheral (COP) circuit structure.

Referring to FIG. 4, the memory device 10a may include the peripheral circuit 12 formed at a first level on a substrate 200, a first semiconductor layer 100a, and the memory cell array 11 formed at a second level on the substrate 200. The memory device 10a may include an insulating film 270 interposed between the peripheral circuit 12 and the first semiconductor layer 100a.

The peripheral circuit 12 disposed in a peripheral circuit area PA may include a page buffer, a latch circuit, a cache circuit, a column decoder, a row decoder, a sense amplifier, and/or data input/output circuit.

The memory cell array 11 disposed in the memory cell array area MCA may include the circuit structure of FIG. 2 and FIG. 3.

As used herein, the term “level” may mean a height in the vertical direction (e.g., the z direction) from the substrate 200. Regarding the substrate 200, the first level may be closer to the substrate 200 than the second level.

In an exemplary embodiment of the inventive concept, the substrate 200 may have a main surface extended in the x direction and the y direction. The substrate 200 may include Si, Ge and/or SiGe. The substrate 200 may include a silicon-in-insulator (SOI) substrate, and/or a germanium-on-insulator (GeOI) substrate.

In the peripheral area PA of the substrate 200, an active region may be defined by a device isolation layer 210. In the active region of the substrate 200, a p-type well 212 for the peripheral circuit and a n-type well 214 for the peripheral circuit may be formed. A metal-oxide-semiconductor (MOS) transistor may be formed on the p-type well and the n-type well. A plurality of transistors may include a gate 224, a gate insulating film 222, and source/drain region 228, respectively. Both sidewalls of the gate 224 may be covered by insulating spacers 226. An etch stop layer 220 may be formed on the gate 224 and the insulating spacers 226. The etch stop layer 220 may include an insulating material such as silicon nitride, or silicon oxynitride.

A plurality of interlayer insulating layers 240, 250, 260 may stacked sequentially on the etch stop layer 220. The plurality of interlayer insulating layers 240, 250, 260 may include silicon oxide, silicon nitride, and silicon oxynitride.

A plurality of transistors may be connected electrically to a multilayer interconnection structure 230. The multilayer interconnection structure 230 may be insulated by the interlayer insulating layers 240, 250, 260.

The multilayer interconnection structure 230 may be sequentially stacked in order on the substrate 200. The multilayer interconnection structure 230 may include a first contact 232, a first interconnection layer 234, a second contact 236, and a second interconnection layer 238. The multilayer interconnection structure 230 may be electrically connected to the first contact 232, the first interconnection layer 234, the second contact 236, and the second interconnection layer 238. In an exemplary embodiment of the inventive concept, the first interconnection layer 234 and the second interconnection layer 238 may include a metal, a conductive metal nitride, and/or a metal silicide. For example, the first interconnection layer 234 and the second interconnection layer 238 may include a conductive material such as tungsten, molybdenum, titanium, cobalt, tantalum, nickel, tungsten silicide, titanium silicide, cobalt silicide, tantalum silicide, and nickel silicide.

In FIG. 4, it is described that the multilayer interconnection structure 230 has an interconnection structure of a second level including the first interconnection layer 234 and the second interconnection layer 238. However, the inventive concept is not limited thereto. For example, the multilayer interconnection structure may be higher than the second level according to the layout of the peripheral circuit area PA, the type of gate 224, and the arrangement of the gate 224. In the multilayer interconnection structure 230 of FIG. 4, it is assumed that the second interconnection layer 238 is the uppermost interconnection layer among interconnection layers forming the multilayer interconnection structure 230. In addition, it is assumed that the third interlayer insulating layer 260 among the plurality of interlayer insulating layers 240, 250, 260 is the uppermost interlayer insulating layer covering the second interconnection layer 238.

The first semiconductor layer 100a may be formed on the third interlayer insulating layer 260. Vertical memory cells may be formed on the first semiconductor 100a. In an exemplary embodiment of the inventive concept, the first semiconductor layer 100a may include impurity doped polysilicon. For example, the first semiconductor layer 100a may include a p-type impurity doped polysilicon. In addition, the first semiconductor layer 100a may be formed to a height of about 20 nm to about 500 nm. However, the height of first semiconductor layer 100a is not limited hereto.

The memory cell array area MCA may be formed on the first semiconductor layer 100a. The vertical memory cells may be disposed in the memory cell array area MCA. For example, the memory cell array area MCA may be a first well area 110 formed in the first semiconductor layer 110a.

The plurality of gate conductive layers 120 and insulating layers 121 may be stacked on the upper surface of the first well area 110. The channel layer 130 and the common source line CSL may be formed on the upper surface of the first well area 110. The channel layer 130 may be perpendicular to the upper surface of the first well area 110, and formed by penetrating the plurality of gate conductive layers 120 and insulating layers 121. In addition, the common source area 142 may be formed in the first well area 110. The common source area 142 may be extended along an extending direction of the word line cut area WLC (e.g., the x direction).

A detailed description regarding the structure of the memory cell array 11 of FIG. 4 will be omitted because its structure is almost identical with the structure of memory cell array of FIG. 1a to FIG. 1c.

As described above, the plurality of gate layers 120 may include the first edge area 120a. Some of the first edge area 120a may be disposed outside of the memory cell array area MCA. The first edge area 120a may be physically and electrically separated from the other areas of the gate conductive layer 120 by the word line cut area WLC. The first edge area 120a may be floated.

In the memory device 10a, at least one edge area of the gate conductive layer 120 may disposed outside of the first well area 110. The peripheral circuit 12 may be disposed under the memory cell array 11. Therefore, the size of the semiconductor chip mounted the memory device 10a may be reduced.

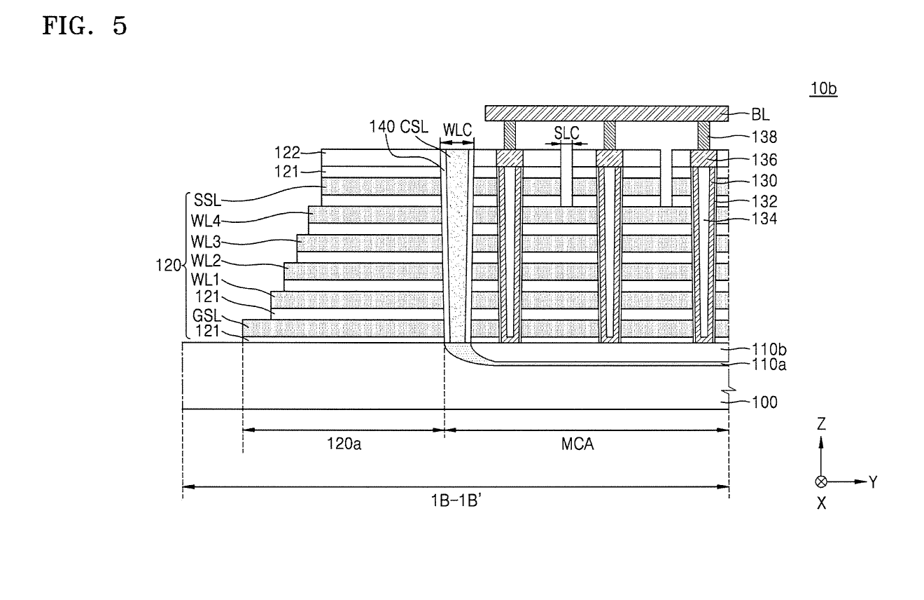

FIG. 5 is a cross sectional diagram of a memory device 10b according to an exemplary embodiment of the inventive concept. A layout of the memory device 10b is almost identical with that shown in FIG. 1a. FIG. 5 is a cross sectional view of line 1B-1B′ of FIG. 1a.

A configuration of the memory device 10b of FIG. 5 may be substantially the same as the memory device 10a of FIG. 1a to FIG. 1c; accordingly, most of the overlapping description is omitted. The memory cell array MCA may include the plurality of well areas 110a, 100b. The first well area 110a and the second well area 110b may be different conductive well areas with respect to each other. The first well area 110a may be an n-type well. The second well area 110b may be a p-type well. The second well area 110b may be formed in the first well area 110a. The first well area 110a may surround the second well area 110b on the substrate 100. This well area structure may increase electrical properties of the memory cell array 11 in that the first well area 110a minimizes an electrical effect between the second well area 120b and the substrate 100.

In the first well area 100a, the common source line CSL may be formed at a part adjacent to the first edge area 110a of the gate conductive layer 120. However, it is not limited thereto, and the common source line CSL may be formed on the second well area 110b.

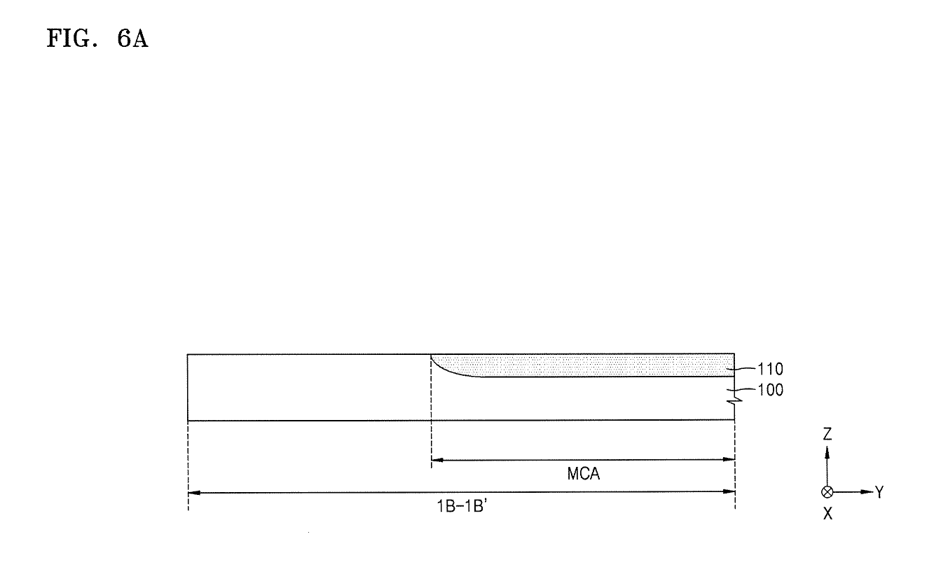

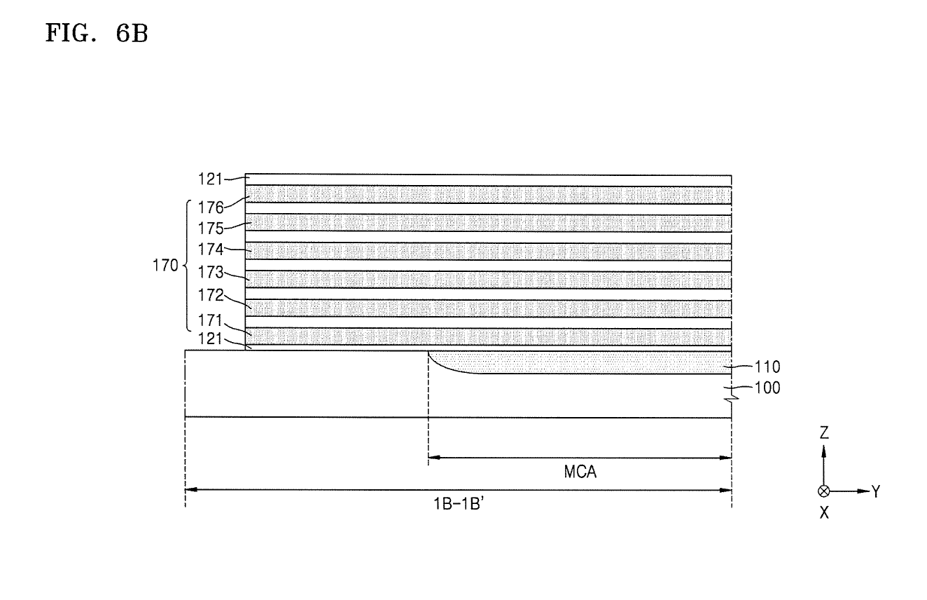

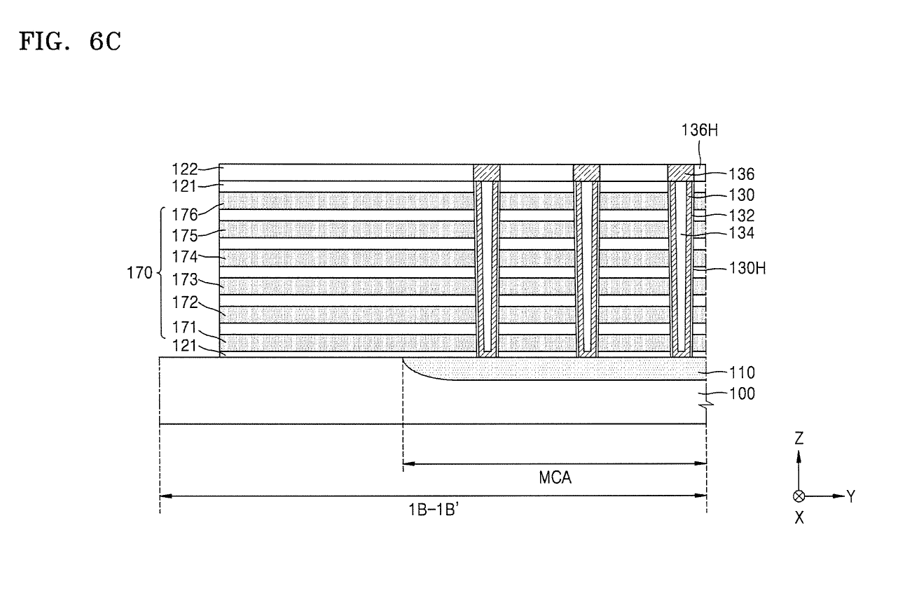

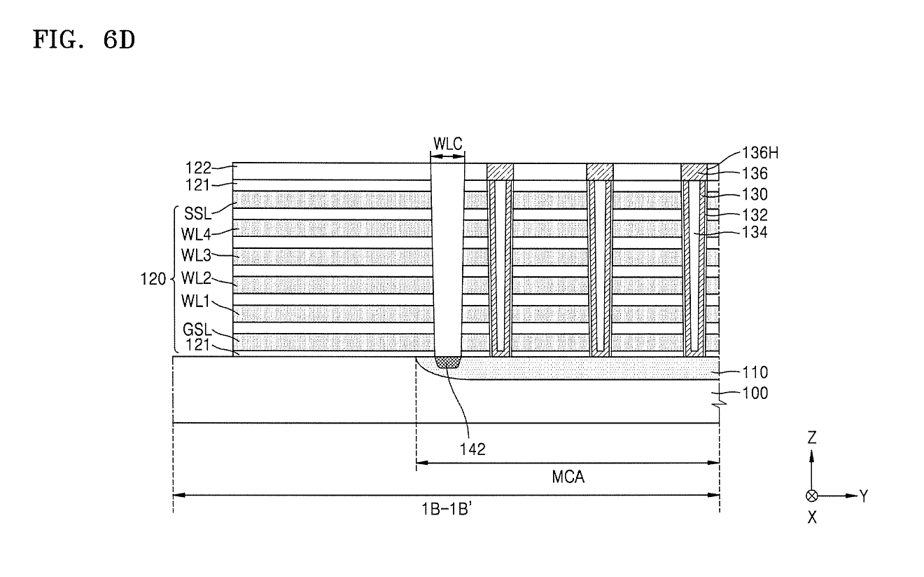

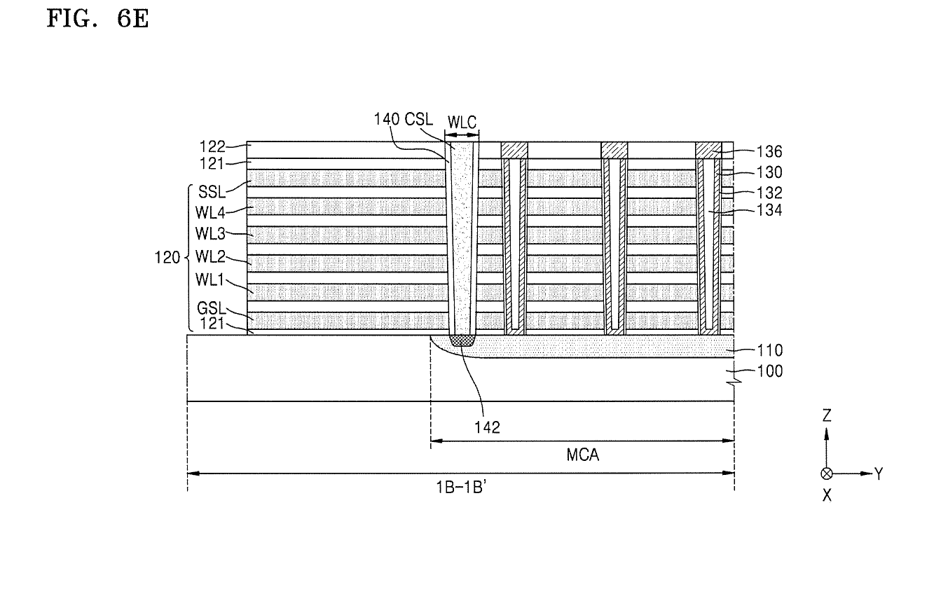

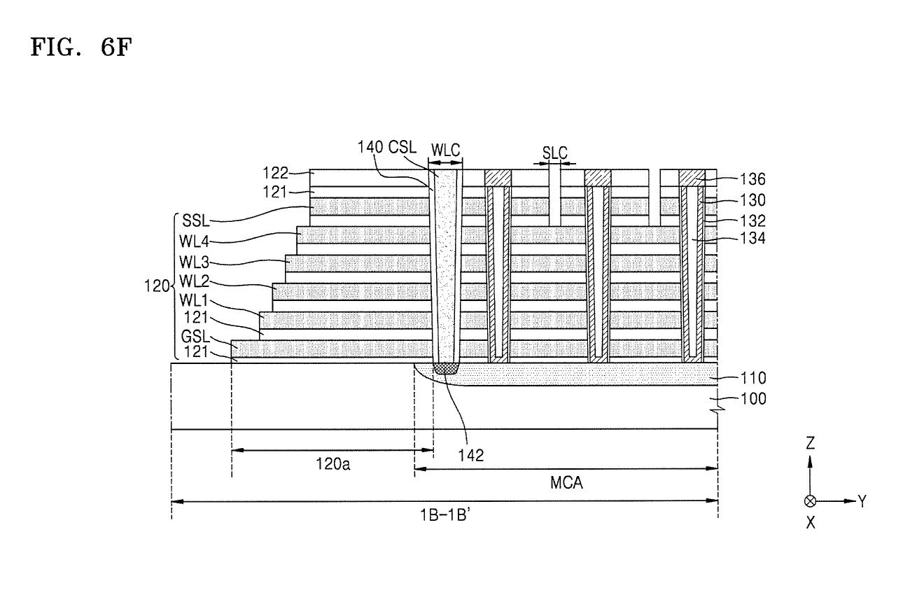

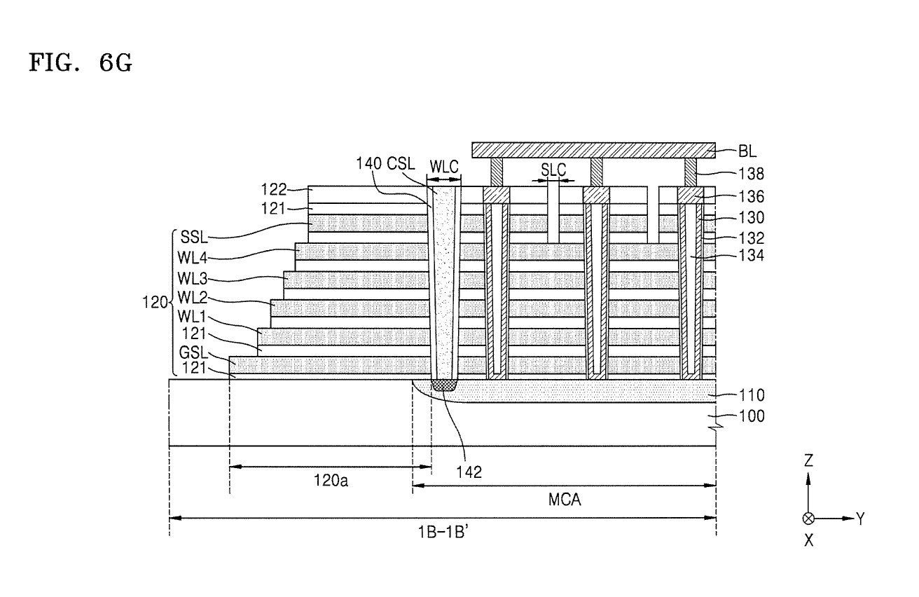

FIG. 6a through FIG. 6g are cross sectional diagrams illustrating a method of manufacturing a memory device according to an exemplary embodiment of the inventive concept.

The manufacturing method may correspond to the memory device of FIG. 1a to FIG. 1c. In particular, the method will be described on the basis of the cross sectional diagram of the 1B-1B′ line shown in FIG. 1b.

Referring to FIG. 6a, the memory cell area MCA may be formed on the substrate 100. The memory cell area MCA may be formed by forming well area 110 in an area on the substrate 100. The well area 110 may be formed by doping a first impurity in an area on the substrate 100. The first impurity may be a p-type impurity. The first impurity may be doped by an ion implantation process.

Referring to FIG. 6b, preliminary gate stack structure 170 may be formed on the substrate 100. The preliminary gate stack structure 170 may be formed by alternately stacking the insulating layers 121 and first to the sixth preliminary gate layers 171˜176 on the substrate 100. For example, the insulating layer 121 may be formed with a predetermined height using silicon oxide, silicon nitride, and silicon oxynitride. In addition, the preliminary gate layers 171˜176 may be formed with a predetermined height using silicon nitride, silicon carbide, and polysilicon. A length of the second direction (e.g., the y direction) of the insulating layers 121 and the preliminary gate layers 171˜176 may be longer than a length of the well area 110. Thus, a portion of the insulating layers 121 and a portion of the preliminary gate layers 171-176 may be disposed outside of the well area 110.

The preliminary gate layers 171˜176 may be preliminary layers or sacrificial layers used to form a ground selection line GSL of FIG. 6f, a plurality of word lines WL1˜WL4 of FIG. 6f, and a string selection line SSL of FIG. 6f in later steps, respectively. A number of the preliminary gate layers 171˜176 may be selected according to a number of the ground selection line, the word lines and the string selection line.

Referring to FIG. 6c, a channel hole 130H may be formed by penetrating the preliminary gate stack structure 170. The channel hole 130H may be extended in a third direction perpendicular to the main surface of the substrate 100 on the well area 110. A plurality of channel holes 130H may be formed and spaced apart from each other in the first direction and the second direction. The upper surface of the well area 110 may be exposed in the bottom of the channel holes 130H.

In FIG. 6c, it is illustrated that a part of the well area 110 exposed in the bottom of the channel hole 130H is flat. However, a recess may be formed in the upper surface of the well area 110 by over-etching the bottom of the channel hole 130H.

A preliminary gate insulating film may be formed on the preliminary gate stack structure 170. In addition, the preliminary gate insulating film may be formed on the upper surface of the well area 110 exposed at the bottom of channel hole 130H and a channel hole sidewall. Hereafter, a part of the preliminary gate insulating film may be removed which is formed on the preliminary gate stack structure 170 and the channel hole 130H bottom, by performing an anisotropic etching process on the preliminary gate insulating film. Thus, a gate insulating film 132 may be formed in the sidewall of channel hole 130H. Therefore, the upper surface of the well area 110 may be exposed again to the channel hole 130H bottom.

The gate insulating film 132 may be formed evenly on the sidewall of the channel hole 130H with a predetermined width. The gate insulating film 132 may partially fill the inside of channel hole 130H.

Hereafter, a conductive layer and an insulating layer may be formed sequentially on an inside wall of the channel hole 130H and the preliminary gate stack structure 170. Then, upper surfaces of the conductive layer and the insulating layer may be flattened until the upper surface of preliminary gate stack structure 170 is exposed. Thus, a channel layer 130 and a buried insulating film 134 may be formed on the inside wall of the channel hole 130H. The bottom of channel layer 130 may be connected to the surface of the upper surface of the well area 110 exposed at the bottom of channel layer 130. The outside wall of channel layer 130 may be connected to the gate insulating layer 132. The channel layer 130 may be formed by a chemical vapor deposition (CVD) process, a low pressure CVD (LPCVD) process, and/or an atomic layer deposition (ALD) process, using impurity doped polysilicon. In addition, the channel layer 130 may be formed using impurity undoped polysilicon. The buried insulating film 134 may be formed by the CVD process, LPCVD process, and/or ALD process using silicon oxide, silicon nitride, and/or silicon oxynitride.

Hereafter, the etch stop layer 122 may be formed on the preliminary gate stack structure 170. The etch stop layer 122 may cover the channel layer 130, the buried insulating film 134, and the gate insulating layer 132. The etch stop layer 122 may be formed using silicon nitride, silicon oxide, and/or silicon oxynitride.

A drain hole 136H may be formed in the etch stop layer 122. The drain hole 136H may expose the upper surfaces of channel layer 130 and buried insulating film 134. Hereafter, a conductive layer filling the drain hole 136H may be formed and a drain region 136 may be formed by flatting the upper surface of the conductive layer. An upper surface of drain region 136 may be formed at the same level of the upper surface of etch stop layer 122.

Referring to FIG. 6d, the word line cut area WLC may be formed by penetrating the plurality of insulating layers 121 and the preliminary gate stack structure 170. The word line cut area WLC may expose the well area 110. A common source area 142 may be formed by implanting an impurity ion in the well area 110 through the word line cut area WLC. The plurality of preliminary gate layers 171˜176 may be replaced by the plurality of gate conductive layers 120, for example, the ground selection line GSL, the plurality of word lines WL1˜WL4, and the string selection line SSL. Referring to FIG. 6b, some of the plurality of preliminary gate layers 171˜176 may be disposed outside of the well area 110. Thus, the some of the plurality of preliminary gate layers 171˜176 may not overlap the well area 110 in the vertical direction.

When the plurality of preliminary gate layers 171˜176 are replaced by the plurality of gate conductive layers 120, if the plurality of preliminary gate layers 171˜176 include poly-silicon, the plurality of preliminary gate layers 171˜176 may be formed using a silicide process. In this case, the ground selection line GSL, the plurality of word lines WL1˜WL4, and the string selection line SSL may include tungsten silicide, tantalum silicide, cobalt silicide, or nickel silicide, respectively. However, present inventive concept is not limited thereto and may include any other type of silicide.

In an exemplary embodiment of the inventive concept, after the plurality of preliminary gate layers 171˜176 exposed through the word line cut area WLC are selectively removed, the ground selection line GSL, the plurality of word lines WL1˜WL4, and the string selection line SSL may be formed by filling a conductive material into an empty space between the plurality of conductive layers 121. In this case, the ground selection line GSL, the plurality of word lines WL1˜WL4, and the string selection line SSL may be formed using a metal material such as tungsten, tantalum, and nickel.

Referring to FIG. 6e, a common source spacer 140 and the common source line CSL may be formed in a plurality of the word line cut areas WLC, respectively.

The common source line spacer 140 may be formed by silicon oxide, silicon nitride, or silicon oxynitride. The common source line CSL may be formed by a conductive material. For example, the common source line CSL may be formed using a metal material such as tungsten W, aluminum Al, copper Cu. In an exemplary embodiment of inventive concept, a metal silicide layer may be interposed between the common source area 142 and the common source line CSL for reducing contact resistance. For example, the metal silicide layer may be formed by cobalt silicide.

Referring FIG. 6f, after forming an insulating film which is covering the common source line CSL and the plurality of drain areas 136, a string selection line cut SLC may be formed by removing some of the string selection line SSL and the insulating layer 121. The string selection line cut SLC may be filled by an insulating film.

Hereafter, the ground selection line GSL, the word lines WL1˜WL4, and the string selection line SSL may be patterned using a plurality of patterning processes using a mask. The insulating layers 121 may be patterned aligned with an adjacent gate conductive layer 120. Some of the edge area 120a of the patterned gate conductive layer 120 may be disposed outside of the well area 110. Hereafter, an insulating film covering the etch stop layer 122 and sidewalls of the patterned gate conductive layer 120 may be formed.

Referring to FIG. 6g, a plurality of bit line contact holes may be formed by removing some of the insulating film covering the plurality of drain areas 136. The plurality of bit line contact holes may expose the plurality of drain areas 136. A plurality of bit line contacts 138 may be formed by filling the plurality of bit line contact holes with a conductive material. Hereafter, a bit line BL connected to the bit line contact 138 may be formed.

By the processes described above, the memory device 10 of FIG. 1a through FIG. 1c may be formed.

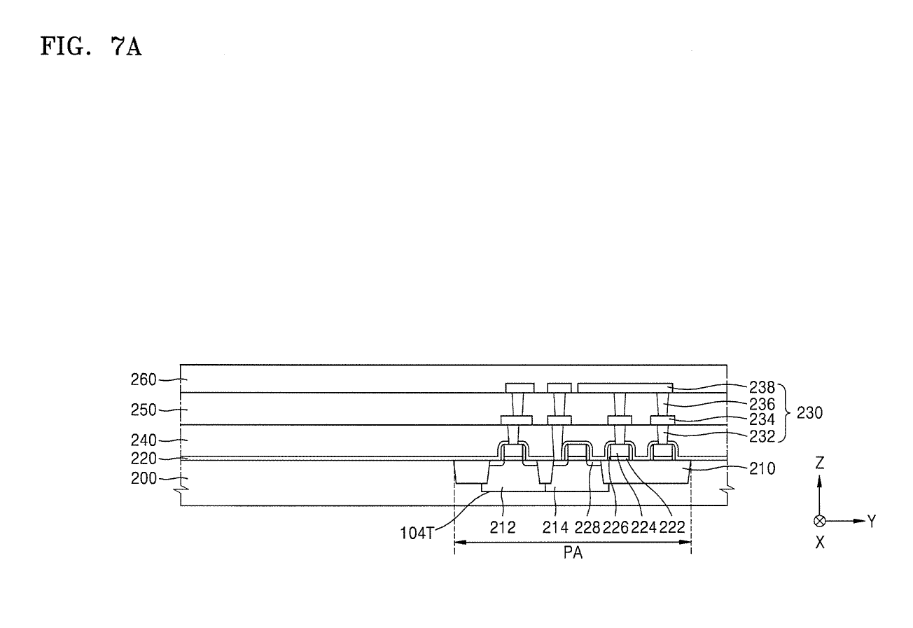

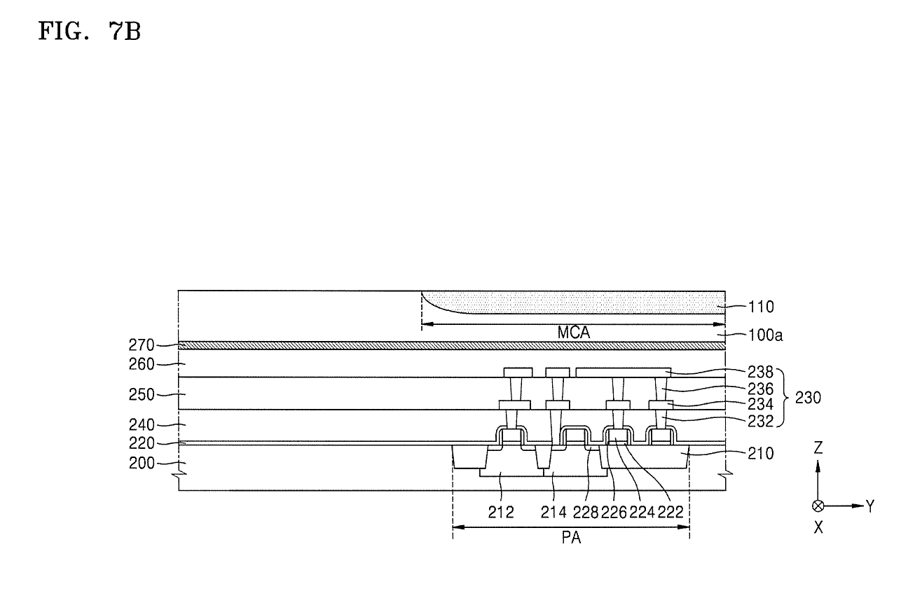

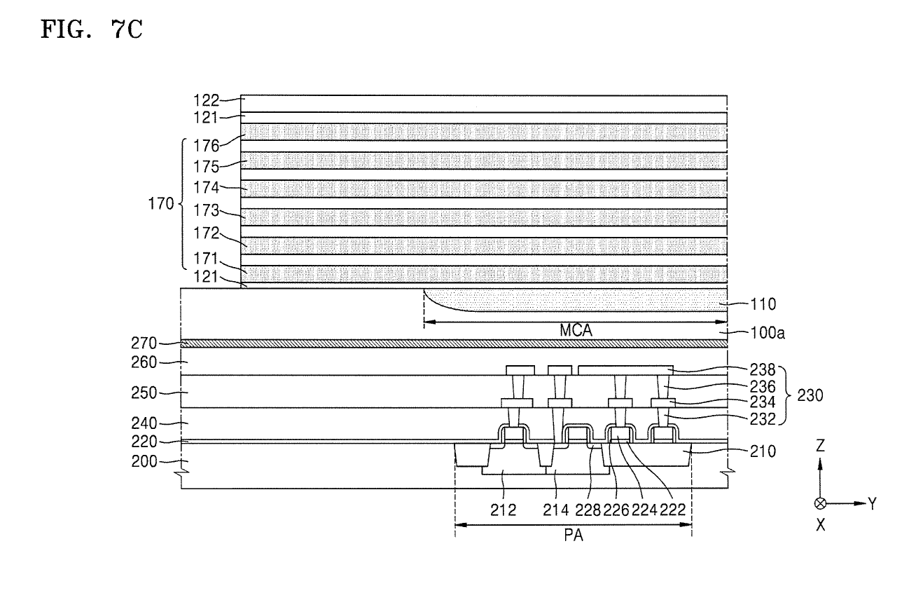

FIG. 7a through FIG. 7d are cross sectional diagrams illustrating a manufacturing method of a memory device according to an exemplary embodiment of inventive concept. In this embodiment, the manufacturing method of the memory device will be described with reference to the memory device 10a of FIG. 4.

Referring to FIG. 7a, a peripheral area PA may be formed in an area on a substrate 200. For example, trench 104T is formed on the substrate 200, and an active area may be formed by filling the trench 104T with an insulating material such as silicon oxide. Then, a peripheral circuit p-type well 212 and peripheral circuit n-type well 214 may be formed by performing a plurality of ion implantation processes on the substrate 200. N-type MOS (NMOS) transistors may be formed in the peripheral circuit n-type well 214. P-type MOS (PMOS) transistors may be formed in the peripheral circuit p-type well 212.

A gate insulating layer 222 for the peripheral circuit may be formed on the substrate 200. Then, a gate 224 for the peripheral circuit may be formed on the gate insulating layer 222. The gate 224 may be formed by doped polysilicon and/or metal. An insulating spacer 226 may be formed on sidewalls of the gate 224. Source/drain area 228 may be formed at both sides of the gate 224 on the substrate 200. The source/drain area 228 for an NMOS transistor may be formed by implanting an n-type impurity on the substrate 200. The source/drain area 228 for PMOS transistor may be formed by implanting a p-type impurity on the substrate 200. The source/drain area 228 may be lightly doped drain (LDD) structure. Thus, a plurality of transistors including the gate insulating layer 222, gate 224 and source/drain area 228 may be formed.

An etch stop layer 220 may be formed on the plurality of transistors and the insulating spacer 226. The etch stop layer 220 may be formed with silicon nitride, silicon oxynitride, or an insulating material including any combination of these.

A multilayer interconnection structure 230 may be formed on the etch stop layer 220. The multilayer interconnection structure 230 may include a first contact 232, a first interconnection layer 234, a second contact 236, and a second interconnection layer 238. A plurality of interlayer insulating layers 240, 250, 260 may be formed on the etch top layer 220. The plurality of interlayer insulating layers 240, 250, 260 may insulate the multilayer interconnection layer structure 230. The second interconnection layer 238 of the multilayer interconnection structure 230 may be the uppermost interconnection layer.

Referring FIG. 7b, an insulating thin film 270 may be formed on the interlayer insulating layer 260 which covers the second interconnection layer 238. The insulating thin film 270 may be formed with silicon oxide. In an exemplary embodiment of the inventive concept, the insulating thin film may be a barrier metal layer including titanium, tantalum, and titanium nitride.

The first semiconductor layer 100a maybe formed on the insulating thin film 270. The first semiconductor layer 100a may be formed using a chemical vapor deposition process, an atomic layer deposition process, a physical vapor deposition process with poly-silicon doped with the first impurity. In the process of forming the first semiconductor layer 100a, the first impurity may be doped in-situ. In addition, after the first semiconductor layer 100a is formed, the first impurity may be doped by an ion implantation process. The first impurity may be a p-type impurity.

The memory cell array area MCA may be formed in the first semiconductor layer 100a. The memory cell array area MCA may be the well area 110. The well area 110 may be formed on the first semiconductor layer 100a by doping an impurity using an ion implantation mask. The impurity may be an n-type impurity or a p-type impurity.

In the exemplary embodiment of the inventive concept, as described with reference to FIG. 5, the first well area 110a may be formed by doping the second impurity in the first semiconductor layer 110a. The second well area 110b may be formed by doping the first impurity in the first well area 110a. Herein, the first impurity may be an n-type impurity, and the second impurity may be a p-type impurity.

Referring to FIG. 7c, a preliminary gate stack structure 170 may be formed on the first semiconductor layer 100a. The preliminary gate stack structure 170 may be formed by alternately stacking the insulating layers 121 and the first to the sixth preliminary gate layers 171˜176. The second direction (e.g., y direction) length of the insulating layers 121 and the preliminary gate layers 171˜176 may be longer than a length of the well area 110. Therefore, an area of the insulating layers 121 and the preliminary gate layers 171˜176 may be disposed outside of the memory cell array area MCA. Manufacturing step after this, may be substantially the same as those of FIG. 6C˜FIG. 6g. Thus, descriptions thereof are omitted.

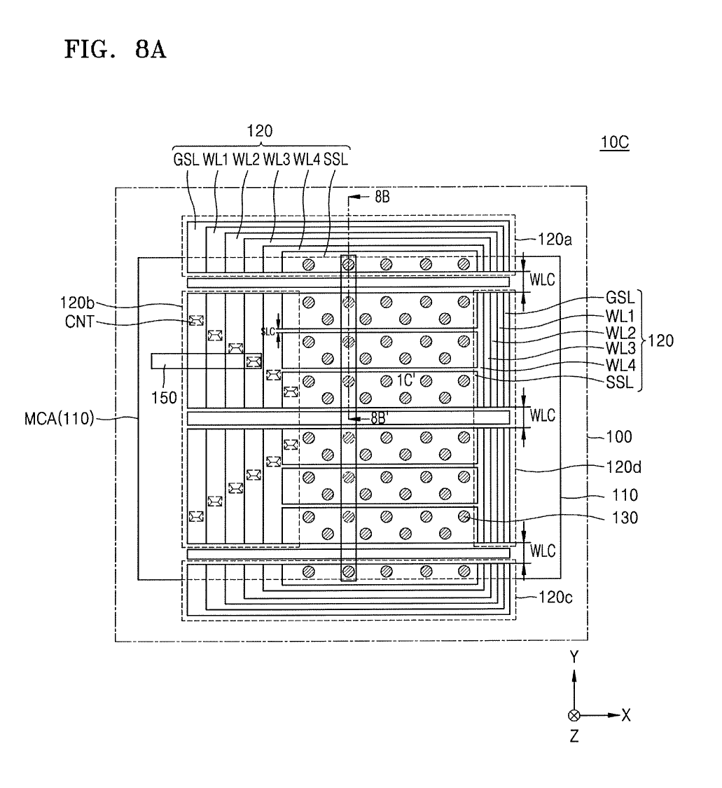

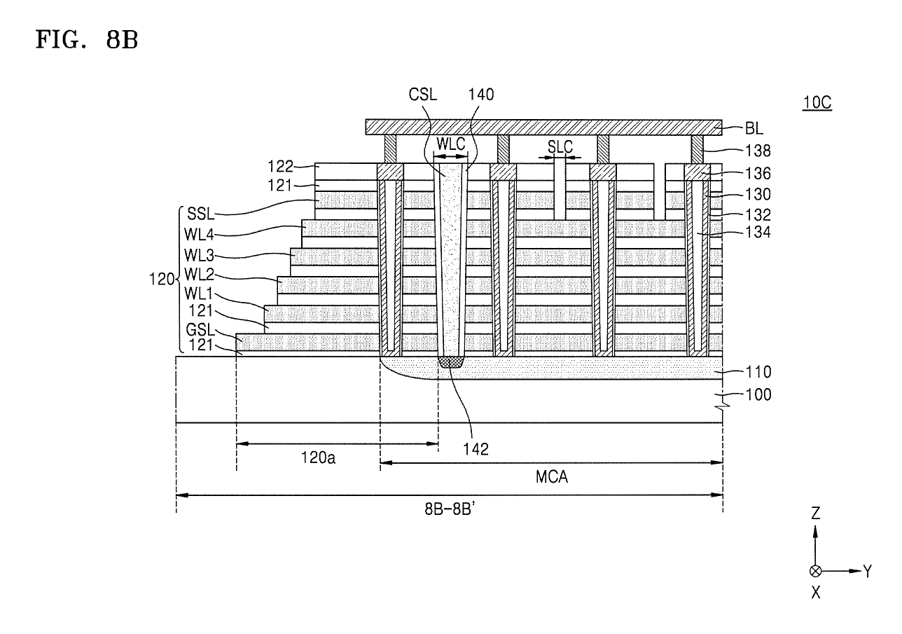

FIG. 8a is a layout diagram illustrating a memory device 10c according to an exemplary embodiment of the inventive concept. FIG. 8b is a cross sectional view of line 8B-8B′ of FIG. 8a.

The layout of the memory device 10c of FIG. 8a is similar to the layout of memory device 10 of FIG. 1a. For example, in FIG. 1a, the channel layer 130 may be not disposed in the first and the third edge area 120a, 120c of the gate conductive layer 120. In FIG. 1a, some of the first and the third edge area 120a, 120c of gate conductive layer 120 is disposed outside of the well area 110. However, in FIG. 8a, the plurality of channel layers 130 may be disposed in the first edge area and the third edge area 120a, 120c. Herein, the channel layer 130 disposed in the first and the thirds edge area 120a, 120c may be dummy memory cells.

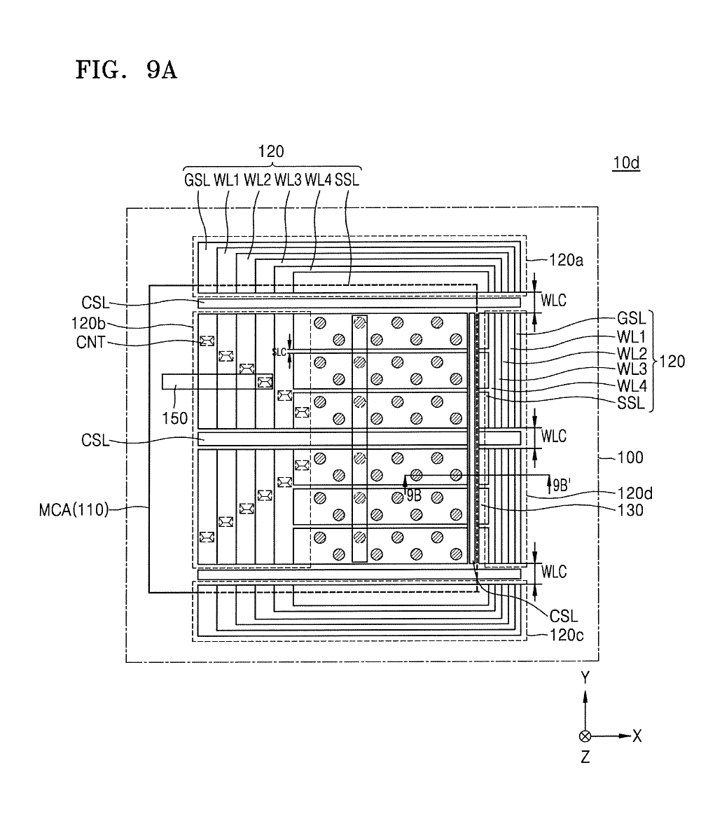

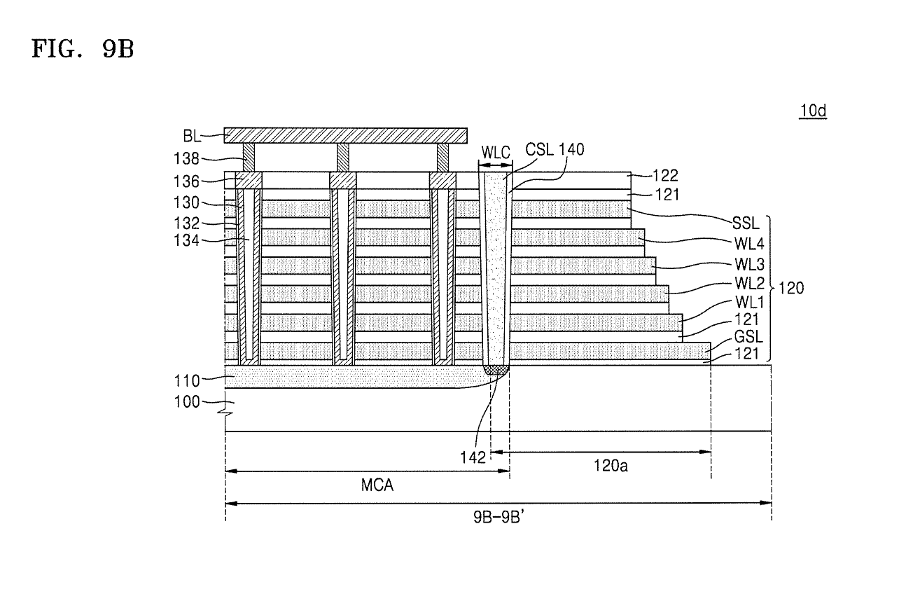

FIG. 9a is a layout diagram of a memory device 10d according to an exemplary embodiment of the inventive concept, and FIG. 9b is a cross sectional view of line 9B-9B′ of FIG. 9a.

Referring to FIG. 9a and FIG. 9b, a plurality of gate conductive layers 120 may be stacked on the memory cell array area MCA, for example, the well area 110. The plurality of gate conductive layers 120 may include a plurality of edge areas 120a-120d. A whole or a part of at least one of the plurality of edge areas 120a˜120d may be disposed outside of the well area 110. Herein, with reference to FIG. 9a, not only are the first and the third edge area 120a, 102c disposed outside of the well area 110 like that shown in FIG. 1a, but the fourth edge area 120d may be disposed outside of the well area 110. The fourth edge area 120d may be electrically separated from the second edge area 120b by the word line cut area WLC. The fourth edge area 120d may maintain a floating state. FIG. 9a further identifies common source lines CSL.

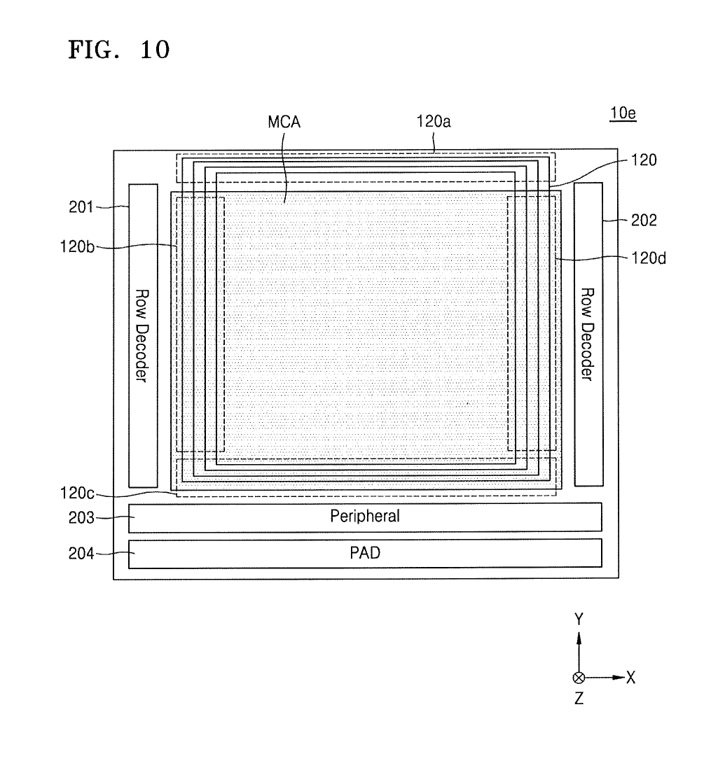

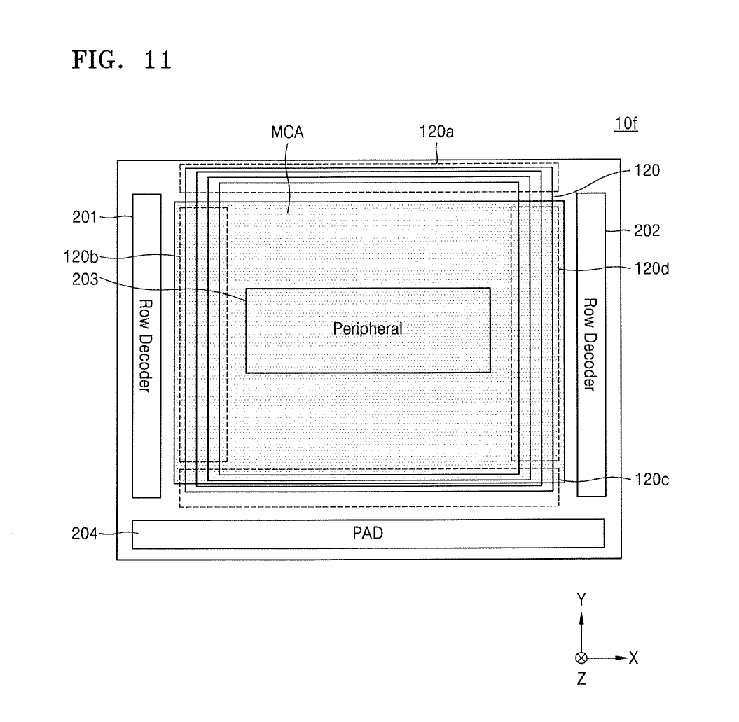

FIG. 10 is a layout diagram illustrating a memory device 10e according to an exemplary embodiment of inventive concept. The layout of FIG. 10 may be a layout of semiconductor chip including a memory cell array. Referring to FIG. 10, the memory device 10e may include a memory cell array area MCA and a plurality of peripheral circuit areas 201, 202, 203. The memory device 10e may include a pad area 204 including a plurality of pads electrically connected to an external device.

The vertical memory cell array described with reference to FIG. 2 and FIG. 3 may be disposed in the memory cell array area MCA. The memory cell array area MCA as described in FIG. 1a and FIG. 1c, may be the well area 110 of FIG. 1a to FIG. 1c disposed in the memory cell array area MCA. The plurality of gate conductive layers 120 may be stacked on the memory cell array area MCA. The plurality of gate conductive layers 120 may be overlapped with the memory cell array area MCA.

The peripheral circuit areas 201, 202, 203 may be disposed in the area surrounding the memory cell array area MCA. The peripheral circuit areas 201, 202, 203 may be in other well areas parallel to the memory cell array area MCA. In the peripheral circuit areas 201, 202, 203, a row decoder, a page buffer, a latch circuit, a cache circuit, a column decoder, a sense amplifier or data input/output circuit may be formed.

Referring to FIG. 10, the row decoder may be formed in the first and the second peripheral circuit areas 201, 202 disposed at both sides of the memory cell array area MCA. Other peripheral circuits may be formed in the third peripheral circuit area 203 disposed under the memory cell array area MCA.

The plurality of gate conductive layers 120 may include edge areas 120a, 120b, 120c, 120d. At least a portion of the first edge area 120a that is not adjacent to the peripheral circuits 201, 202, 203, may be disposed outside of the memory cell array area MCA. Edge areas 120b, 120c, 120d adjacent to the peripheral circuit areas 210, 202, 203 may be disposed in the memory cell array area MCA.

FIG. 11 is a layout diagram illustrating a memory device 10f according to an exemplary embodiment of inventive concept.

Referring to FIG. 11, some of the peripheral circuit areas 201, 202, 203 may be disposed in the memory cell array area MCA. In FIG. 11, the third peripheral circuit area 203 may be disposed under the memory cell array area MCA. This circuit structure is referred to as cell over peripheral (COP) circuit structure, and the COP circuit structure was described with reference to FIG. 5.

In an exemplary embodiment of the inventive concept, a peripheral circuit that can process a data with high speed may be disposed in the third peripheral circuit area 203 disposed under the memory cell array area MCA. The peripheral circuit for processing the data with high speed may receive the data from the memory cell array formed in the memory cell array area MCA. For example, the peripheral circuit may include a page buffer, a latch circuit, a cache circuit, a column decoder, a sense amplifier or data input/output circuit. However, the inventive concept is not limited thereto and may include any other type of peripheral circuit.

In FIG. 11, the first edge area 120a, and a portion of the third edge area 120c disposed in the second direction (e.g., the y direction) may be disposed outside of the memory cell array area MCA. For example, as illustrated in FIG. 11, in the third edge area 120c, some of the conductive layers disposed in a lower portion of the plurality of gate conductive layers 120 may be disposed outside of the memory cell array area MCA. All of the conductive layers disposed in an upper portion of the plurality of gate conductive layers 120 in the third edge area 120c may be disposed inside of the memory cell array area MCA.

FIG. 12 is a layout diagram of a memory device 10g according to an exemplary embodiment of the inventive concept. Referring to FIG. 12, the peripheral circuit areas 201, 202, 203 may be disposed under the memory cell array area MCA. Thus, the peripheral circuits may be formed under the memory cell array area MCA. The second and the fourth edge areas 120b, 120d may be word line pads. The second and the fourth edge areas 120b, 120d may receive electrical signals from the peripheral circuits formed in the first and the second peripheral circuit areas 201, 202. Thus, the second and the fourth edge areas 120b, 120d may be disposed in the memory cell array area MCA. The first edge area 120a and the third edge area 120c may not receive electrical signals from the peripheral circuits formed in the peripheral circuit areas 201, 202, 203. Some part or all of the first and the third edge areas 120a, 120c may be disposed outside of the memory cell array area MCA.

FIG. 13 is a layout diagram of a memory device 10h according to an exemplary embodiment of the inventive concept. Referring to FIG. 13, the memory device 10h may include a plurality of memory cell array areas MCAa, MCAb. The memory cell array areas MCAa, MCAb may be disposed on the left and right sides of the pad region 204. The peripheral circuits 201, 203 may be formed under the memory cell array areas MCAa, MCAb, and the first peripheral circuit area 201 may be disposed adjacent to the pad area 204. The edge area 120d adjacent to the first peripheral circuit area 201 may be formed in the memory cell array area MCAa, and all or some of the other edge areas 120a, 120b, 120c may be formed outside of the memory cell array area MCAa. Hereinabove, various layout structures of the memory devices 10-10h and arrangements of the gate conductive layers 120 were described. However, the inventive concept is not limited thereto, and various modifications may be made.

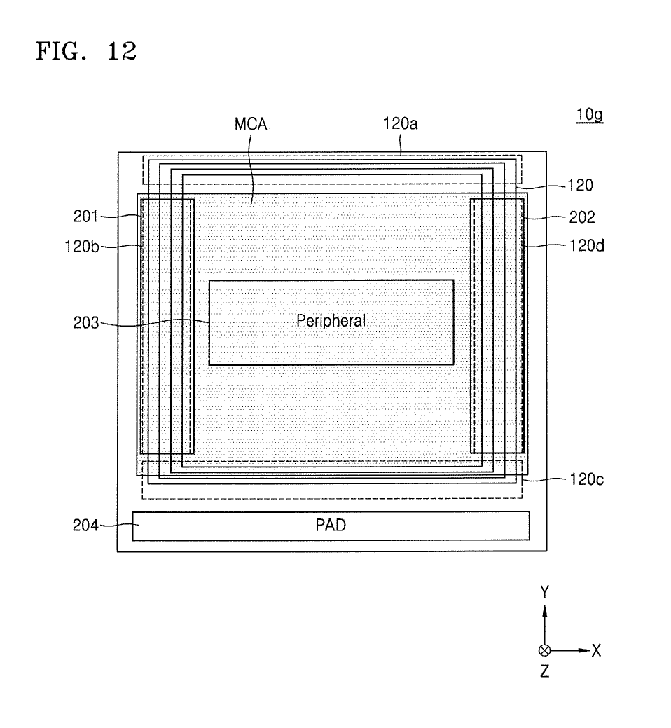

FIG. 14 is a block diagram illustrating a nonvolatile memory device according to an exemplary embodiment of the inventive concept. Referring to FIG. 14, the nonvolatile memory device 1000 may include a cell array 1100, a row decoder 1200, a page buffer 1300, an input/output buffer 1400, a control logic 1500, and a voltage generator 1600.

The cell array 1100 may be connected to the row decoder 1200 via word lines WL or selection lines SSL, GSL. The memory cell array 1100 may be connected to the page buffer 1300 via bit lines BL. The cell array 110 may include a plurality of NAND cell strings. A plurality of cell strings may configure a plurality of memory blocks according to a selection unit or an operation.

Herein, each of the cell strings may be formed in a vertical direction with respect to a base substrate. The plurality of word lines may be stacked in the vertical direction in the cell array 1100. Each channel of the cell strings may be formed in the vertical direction. A word line structure may be formed by stacking the plurality of word lines. Some part of a plurality of edge areas of the word line structure may be formed outside of the memory cell array area. The edge area disposed outside of the memory cell array area may not receive electrical signals, and may maintain a floating state.

The row decoder 1200 may select a memory block of the cell array 1100 in response to an address ADDR. The row decoder 1200 may select a word line WL of the selected memory block. The row decoder 1200 may apply a word line voltage to the selected word line. When programming, the row decoder 1200 may apply a program voltage Vpgm, and a verify voltage Vvfy to the selected word line, and may apply a pass voltage Vpass to unselected word lines. In a read operation, the row decoder 1200 may apply a selected read voltage Vrd to the selected word line, and may apply an unselected read voltage Vread to the unselected word lines. Herein, the row decoder 1200 may apply the unselected read voltage Vread to the selection lines GSL, SSL.

The page buffer 1300 may work as a write driver or a sense amplifier according to an operation mode. When programming, the page buffer 1300 may transmit a bit line voltage corresponding to program data, to the bit line of the cell array 1100.

In a read operation, the page buffer 1300 may sense data stored in the selected memory cell via the bit line. The page buffer 1300 may latch the sensed data, and may transmit the sensed data to an external device. In an erase operation, the page buffer 1300 may float the bit line.

The input/output buffer 1400 may transmit write data received when programming to the page buffer 1300. In the read operation, the input/output buffer 1400 may transmit read data received from the page buffer 1300 to an external device. The input/output buffer 1400 may transmit a received address and command to the control logic 1500 and the row decoder 1200.

The control logic 1500 may control the page buffer 130 and the row decoder 1200 in response to a command CMD received from an external device. The control logic 1500 may control the page buffer 1300, and the voltage generator 1600 to access the selected memory cells in response to the received command CMD.

The voltage generator 1600 may generate various kinds of word line voltages to be applied to the word lines under the control of the control logic 1500. The voltage generator 1600 may generate a voltage to be applied to the well area in which the memory cells are formed. The word line voltages applied to the word lines may be the program voltage Vpgm, the pass voltage Vpass, and the selected and the unselected read voltage Vrd, Vread. The voltage generator 1600 may generate a selection signal to be applied to the string selection line SSL and the ground selection line GSL in the read operation and program operation.

The voltage generator 1600 may generate a voltage for selecting a memory cell in the read operation or a write operation. For example, the voltage generator 1600 may generate voltages to be applied to the word lines and the selection lines (SSL, GSL). The voltages generated by the voltage generator 1600 may be transmitted to the cell array 1100 through the row decoder 1200.

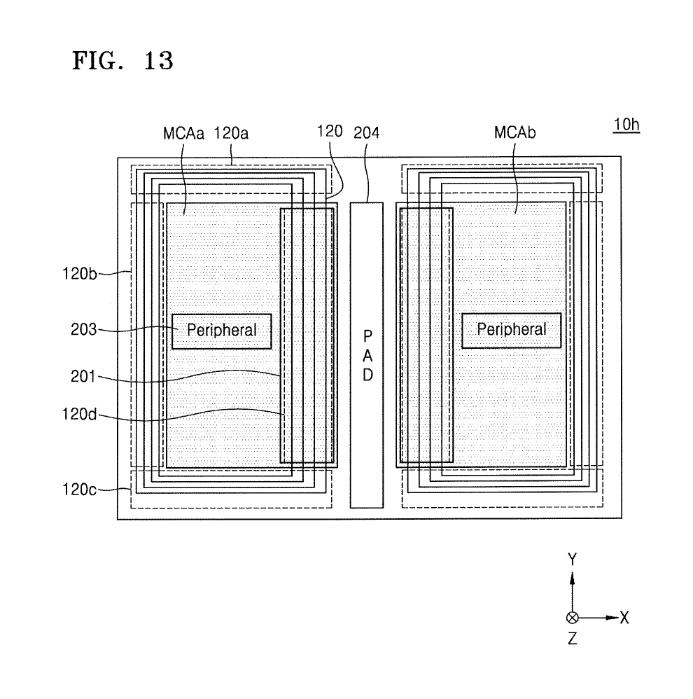

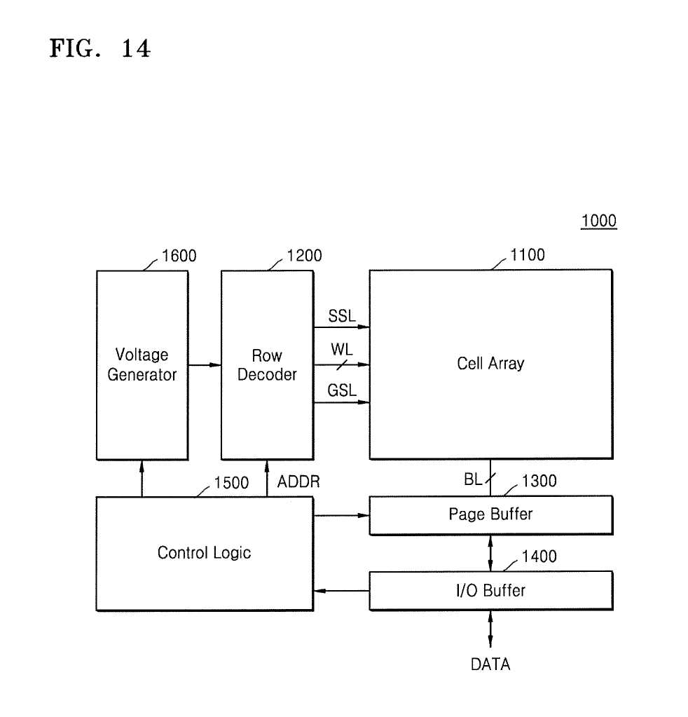

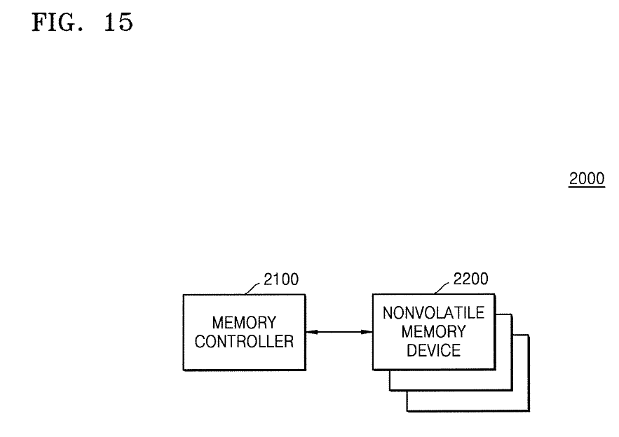

FIG. 15 is a block diagram illustrating a memory system 2000 applied the memory device 10 according to an exemplary embodiment of the inventive concept.

Referring to FIG. 15, the memory system 2000 may include a memory controller 2100 and a plurality of nonvolatile memory devices 2200. The memory controller 2100 may receive data from a host. The memory controller 2100 may store the received data in the plurality of nonvolatile memory devices 2200.

The plurality of nonvolatile memory devices 2200 may include the memory devices 10, 10a, 10b, 10c, 10d, 10e, 10f, 10g, 10h which have layout structures described with reference to FIG. 1a and FIG. 13.

The memory system 2000 may be attached to a host such as a computer, a laptop, a cellular phone, a smart phone, an MP3 player, a personal digital assistant (PDA), a portable multimedia player (PMP), a digital TV, a digital camera, and a portable gate console.

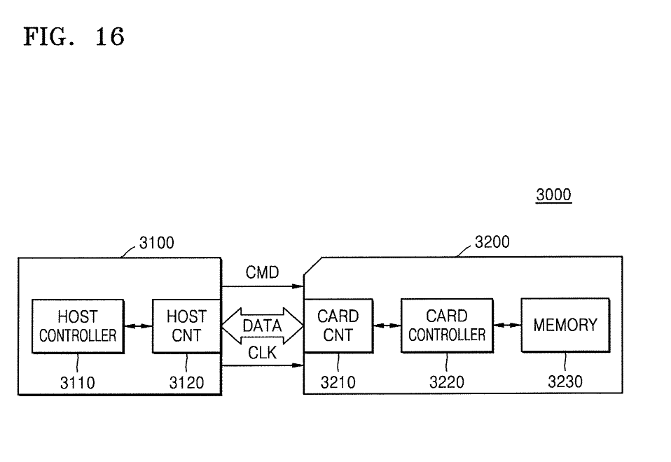

FIG. 16 is a block diagram illustrating a memory card system 3000 applied the memory device according to an exemplary embodiment of the inventive concept.

Referring to FIG. 16, the memory card system 3000 may include a host 3100 and a memory card 3200. The host 3100 may include a host controller 3110 and a host connector 3120. The memory card 3200 may include a card connector 3210, a card controller 3220, and a memory device 3230. Herein, the memory card 3200 may be implemented using the embodiments illustrated in FIG. 1a through FIG. 14.

The host 3100 may program data in the memory card 3200, and may read data stored in the memory card 3200. The host controller 3110 may transmit a command CMD, a clock signal CLK, and data to the memory card 3200 via the host connector 3120. The clock signal CLK may be generated in a clock generator in the host 3100.

The card controller 3220 may store data in the memory device 3230 in response to a command received via the card connector 3210. The card controller 3220 may store the data in the memory device 3230 in synchronization with a clock signal generated in a clock generator in the card controller 3220. The memory device 3230 may store the data received from the host 3100. The memory device 3230 may be one of the memory devices 10, 10a, 10b, 10c, 10d, 10e, 10f, 10g, 10h described above. The size of the memory card 3200 may become smaller as the chip size of the memory device 3230 is reduced.

The memory card 3200 may be a compact flash card (CFC), a micro drive, a smart media card, a multimedia card (MMC), a security digital card (SDC), a memory stick, and a universal serial bus (USB) flash memory driver.

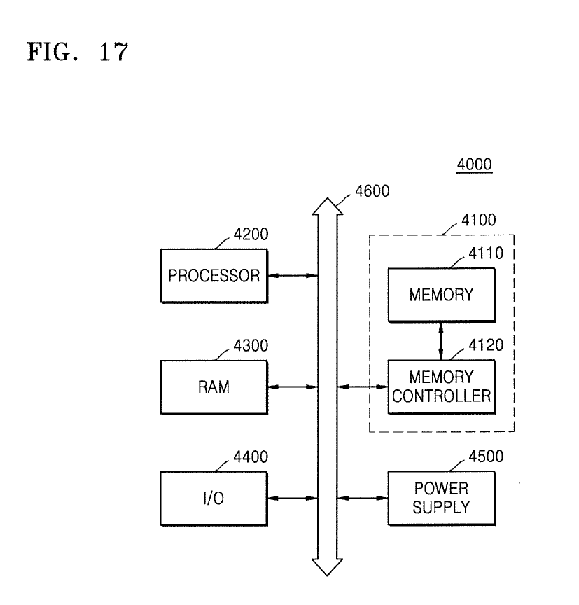

FIG. 17 is a block diagram illustrating a computing system 4000 including a memory system according to an exemplary embodiment of the inventive concept.

Referring to FIG. 17, the computer system 4000 may include a memory system 4100, a processor 4200, a random access memory (RAM) 4300, an input/output device 4400, and a power supply device 4500. The computing system 4000 may communicate with a video card, a sound card, a memory card, and/or a USB device. The computing system 4000 may further include ports to communicate with other electronic devices. The computing system 4000 may be a portable device such as a personal computer, a laptop computer, a cellular phone, a PDA, or a camera.

The processor 4200 may perform a predetermined calculation and/or a task. For example, the processor 4200 may be a micro-processor, or a central processing unit (CPU). The processor 4200 may communicate with the RAM 4300, the input/output device 4400, and the memory system 4100 via a bus 4600 such as an address bus, a control bus, or a data bus. Herein, the memory system 4100 may be implemented using the illustrated embodiments of FIG. 1a through FIG. 14. The memory system 4100 may include a memory 4110 and a memory controller 4120. The memory device having the layout of FIG. 1a through FIG. 13 may be applied to the memory system 4100.

The processor 4200 may be connected to an expansion bus such as a peripheral component interconnect (PCI).

The RAM 4300 may store data used for operations of the computing system 4000. For example, the RAM 4300 may be a dynamic (DRAM), a mobile DRAM, a static RAM (SRAM), a phase-change RAM (PRAM), a ferroelectric RAM (FRAM), a resistive RAM (RRAM), and/or a magnetoresistive (MRAM).

The input/output device 4400 may include input means such as a keyboard, a key pad, and a mouse, and output means such as a printer and display. The power supply device 4500 may provide operation voltages for computer system 4000.

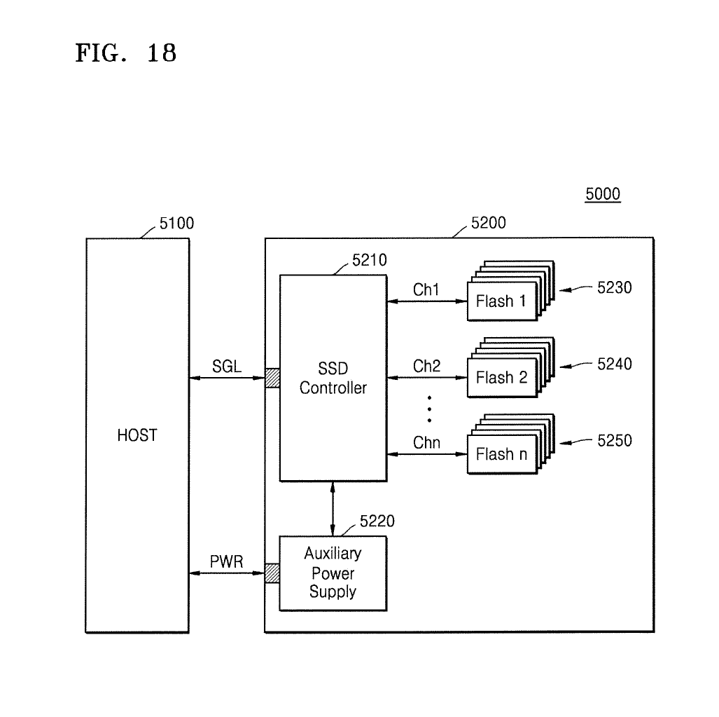

FIG. 18 is a block diagram illustrating a solid state drive (SSD) system 5000 applied to a memory system according to an exemplary embodiment of inventive concept.

Referring to FIG. 18, the SSD system 5000 may include a host 5100 and an SSD 5200. The SSD 5200 may receive and transmit signals SGL to the host via a signal connector. The SSD 5200 may receive a supply voltage PWR via a power connector. The SSD 5200 may include an SSD controller 5210, an auxiliary power supply 5220, and a plurality of memory devices 5230, 5240, 5250. The plurality of memory devices 5230, 5240, 5250 may be vertically stack NAND flash memory devices and may communicate with the SSD controller 5210 via channels CH1 to CH3. Herein, the SSD 5200 may be implemented with the embodiments illustrated in FIG. 1a through FIG. 14. For example, a memory device having the layout of FIG. 1a through FIG. 13 may be applied to the SSD 5200.

While the inventive concept has been particularly shown and described with reference to exemplary embodiments thereof, it will be understood that various changes in form and details may be made therein without departing from the spirit and scope of the inventive concept as defined by the following claims.

1. A nonvolatile memory device, comprising:
a first well area formed on a substrate;
a plurality of channel layers disposed on the first well area and extended in a first direction substantially perpendicular to a surface of the first well area on which the channel layers are disposed; and
a plurality of gate conductive layers stacked on the first well area along side walls of the plurality of channel layers, the plurality of gate conductive layers having a first edge area and a second edge area,
wherein a first part of the first edge area is disposed outside of the first well area.

2. The nonvolatile memory device of claim 1, wherein
the first edge area is adjacent to an edge of the nonvolatile memory device.

3. The nonvolatile memory device of claim 1, wherein
the first edge area is in a floating state.

4. The nonvolatile memory device of claim 1, wherein
the first part of the first edge area is separated from portions of the plurality of gate conductive layers by a word line cut area.

5. The nonvolatile memory device of claim 4, wherein
the word line cut area is disposed in the first well area, and adjacent to a boundary of the first well area.

6. The nonvolatile memory device of claim 1, wherein
the plurality of gate conductive layers are stacked with a step shape, and
at least one gate conductive layer among the plurality of gate conductive layers in the first edge area is disposed outside of the first well area, and at least one gate conductive layer among the plurality of gate conductive layers is disposed in inside the first well area.

7. The nonvolatile memory device of claim 1, further comprising:
a second well area formed adjacent to the first well area on the substrate, wherein
the second edge area of the plurality of gate conductive layers faces the second well area,
wherein the second edge area is disposed inside the first well area.

8. The nonvolatile memory device of claim 7, wherein
the second edge area is electrically connected to a semiconductor element formed in the second well area.

9. The nonvolatile memory device of claim 7, wherein
a row decoder circuit is formed on the second well area, and the row decoder circuit is configured to provide a voltage to the plurality of gate conductive layers.

10. The nonvolatile memory device of claim 1, further comprising:
a semiconductor integrated circuit disposed in another substrate and overlapped with the first well area,
wherein the semiconductor integrated circuit is electrically connected to a memory cell array, and the memory cell array is formed by the plurality of channel layers and the plurality of gate conductive layers.

11. A nonvolatile memory device, comprising:
a memory cell array including a plurality of stacked memory cells; and
a peripheral circuit configured to write and read a data from the memory cell array,
the memory cell array further includes:
a plurality of channel layers extended in a vertical direction from a cell array area formed on a first substrate; and
a plurality of gate conductive layers stacked on the cell array area alongside the plurality of channel layers,
wherein at least one edge area among edge areas of the plurality of gate conductive layers is disposed outside of the cell array area.

12. (canceled)

13. The nonvolatile memory device of claim 11, wherein,
the cell array area includes a first conductive well area and a second conductive well area,
the first conductive well area is formed on the first substrate, and
the second conductive well area is formed on the first conductive well area.

14. (canceled)

15. The nonvolatile memory device of claim 11, wherein
the at least one edge area is disposed in a direction intersecting with an edge area electrically connected to the peripheral circuit.

16. (canceled)

17. The nonvolatile memory device of claim 11, wherein
the peripheral circuit is formed at a same level with the cell array area on the first substrate.

18. The nonvolatile memory device of claim 11, wherein
the peripheral circuit comprises a first peripheral circuit formed alongside the cell array area on the first substrate, and a second peripheral circuit formed on a second substrate, the second peripheral circuit is electrically connected to the memory cell array, and
the second substrate is overlapped by the first substrate.

19. (canceled)

20. The nonvolatile memory device of claim 11, wherein
the peripheral circuit is overlapped by the memory cell array.

21. A method of manufacturing a nonvolatile memory device, comprising:
forming a first well area on a first substrate;
stacking a plurality of conductive layers on the first well area, wherein the plurality of conductive layers are stacked in a vertical direction;
forming a plurality of channel layers extended in the vertical direction from the first well area, wherein the plurality of channel layers are formed by penetrating the plurality of conductive layers; and
patterning the plurality of conductive layers to have steps,
wherein a horizontal length of the first substrate is longer than a horizontal length of the first well area.

22. The method of claim 21, wherein the step of patterning the plurality of conductive layers comprises etching the plurality of conductive layers to form a first edge area of the plurality of conductive layers outside of the first well area.

23-24. (canceled)

25. The method of claim 21, further comprising:
forming a second well area; and
forming a peripheral circuit on the second well area,
wherein the peripheral circuit controls a memory element formed on the first well area,
the step of patterning comprises patterning a second edge area of the plurality of conductive layers to be disposed outside of the first well area, and the second edge area is not adjacent to the second well area.

26-29. (canceled)
